(19) United States
(12) Patent Application Publication
(10) Pub. No.: US 2012/0033695 A1
(43) Pub. Date: Feb. 9, 2012

(54) SEMICONDUCTOR LASER APPARATUS AND OPTICAL APPARATUS

(75) Inventors: Nobuhiko HAYASHI, Osaka-shi (JP); Hideki YOSHIKAWA, Takarazuka-shi (JP); Keiichi KURAMOTO, Kadoma-shi (JP); Takenori GOTO, Moriguchi-shi (JP); Yoshio OKAYAMA, Moriyama-shi (JP); Seiichi TOKUNAGA, Toyonaka-shi (JP)

(73) Assignee: SANYO ELECTRIC CO., LTD., Moriguchi-shi (JP)

(21) Appl. No.: 13/191,683

(22) Filed: Jul. 27, 2011

(30) Foreign Application Priority Data
Aug. 4, 2010 (JP) 2010-175698

(51) Int. Cl. H01S 5/022

(52) U.S. Cl. 372/43.01

(57) ABSTRACT

This semiconductor laser apparatus includes a package constituted by a plurality of members, having sealed space inside and a semiconductor laser chip arranged in the sealed space, while surfaces of the members located in the sealed space are covered with a covering agent made of an ethylene-polyvinyl alcohol copolymer.

### CROSS-REFERENCE TO RELATED APPLICATION

The priority application number JP2010-175698, Semiconductor Laser Apparatus and Optical Apparatus, Aug. 4, 2010, Nobuhiko Hayashi et al., upon which this patent application is based is hereby incorporated by reference.

### BACKGROUND OF THE INVENTION

1. Field of the Invention

The present invention relates to a semiconductor laser apparatus and an optical apparatus, and more particularly, it relates to a semiconductor laser apparatus comprising a package sealing a semiconductor laser chip and an optical apparatus employing the same.

2. Description of the Background Art

A semiconductor laser device has been widely applied as a light source for an optical disc system, an optical communication system or the like in general. For example, an infrared semiconductor laser device emitting a laser beam having a wavelength of about 780 nm has been put into practice as a light source for reading of a CD, and a red semiconductor laser device emitting a laser beam having a wavelength of about 650 nm has been put into practice as a light source for writing/reading of a DVD. A blue-violet semiconductor laser device emitting a laser beam having a wavelength of about 405 nm has been put into practice as a light source for a Btu-ray disc.

In order to attain such a light source apparatus, a semiconductor laser apparatus comprising a package sealing a semiconductor laser chip is known in general, as disclosed in each of Japanese Patent Laying-Open Nos. 9-205251 (1997), 10-209551 (1998) and 2009-135347, for example.

Japanese Patent Laying-Open No. 9-205251 (1997) discloses a plastic-molded apparatus of a semiconductor laser comprising a header formed with a flange surface and made of a resin product, a semiconductor laser chip mounted on the header and a transparent cap of resin covering the periphery of the semiconductor laser chip. In this plastic-molded apparatus, an edge of an opening of the transparent cap is bonded onto the flange surface of the header through an adhesive containing an epoxy resin-based material, whereby the semiconductor laser chip is hermetically sealed.

Japanese Patent Laying-Open No. 10-209551 (1998) discloses a semiconductor laser apparatus comprising a header made of a resin product, a semiconductor laser chip mounted on a chip set portion of the header and a transparent cap (lid member) of resin having an L-shaped cross section. In this semiconductor laser apparatus, an outer edge of the transparent cap is bonded to the chip set portion of the header through a photosetting adhesive or the like, whereby the semiconductor laser chip is hermetically sealed.

Japanese Patent Laying-Open No. 2009-135347 discloses an optical module comprising a substrate made of a metal material, a surface-emitting laser chip mounted on an upper surface of the substrate and a package member (sealing member) sealing space in the periphery of a laser beam source. The package member of this optical module is made of a resin material other than a metal material. For example, an ethylene-polyvinyl alcohol copolymer (EVOH resin) is shown as an example of this resin material.

However, in the semiconductor apparatus disclosed in each of Japanese Patent Laying-Open Nos. 9-205251 (1997) and 10-209551 (1998), the epoxy resin-based adhesive, or the photosetting adhesive or the like is employed to bond the header and the transparent cap to each other. If these adhesives contain many volatile gas components such as organic gas especially before being hardened, a package may be filled with the aforementioned volatile gas after bonding. Further, the header and the transparent cap are made of a resin material, and hence low molecular siloxane, volatile organic gas or the like existing outside the semiconductor apparatus (in the atmosphere) may penetrate into the resin material and enter the package. In this case, an adherent substance is easily formed on a laser emitting facet of the semiconductor laser chip by exciting and decomposing the low molecular siloxane or the volatile gas by a high-energy laser beam having a short lasing wavelength especially if a blue-violet semiconductor laser chip is sealed. In this case, the adherent substance absorbs the laser beam, and hence the temperature of the laser emitting facet is easily increased. Consequently, the semiconductor laser chip is disadvantageously deteriorated.

In the optical module (semiconductor apparatus) disclosed in Japanese Patent Laying-Open No. 2009-135347, low molecular siloxane, volatile organic gas or the like existing outside the optical module (in the atmosphere) may penetrate into a resin material and enter the package member if the package member is made of the resin material. At this time, as to the EVOH resin having a thickness increased to such an extent as to form the package member, cracks are easily generated in members due to an impact from outside or the like. In this case, the low molecular siloxane, the volatile organic gas or the like existing outside may penetrate into clearances of the cracks and enter the package member. In this case, an adherent substance formed on a laser emitting facet absorbs a laser beam, and hence the temperature of the laser emitting facet is easily increased. Consequently, the semiconductor laser chip is disadvantageously deteriorated.

### SUMMARY OF THE INVENTION

A semiconductor laser apparatus according to a first aspect of the present invention comprises a package constituted by a plurality of members, having sealed space inside, and a semiconductor laser chip arranged in the sealed space, wherein surfaces of the members located in the sealed space are covered with a covering agent made of an ethylene-polyvinyl alcohol copolymer.

In the semiconductor laser apparatus according to the first aspect of the present invention, as hereinabove described, the surfaces of the members constituting the package located in the sealed space are covered with the covering agent made of the ethylene-polyvinyl alcohol copolymer (EVOH). The EVOH is a resin material having excellent gas barrier properties, and hence the covering agent covering the aforementioned members can block volatile organic gas from penetrating into the sealed space of the package even if the volatile organic gas is generated from the members located in the sealed space of the package. Further, even if low molecular siloxane, volatile organic gas or the like existing outside the semiconductor laser apparatus (in the atmosphere) penetrates into the components of the package, the covering agent covering the aforementioned members can inhibit the low molecular siloxane, the volatile organic gas or the like from entering the package. Further, the EVOH hardly generates the aforementioned volatile component, and hence the semiconductor laser chip in the package is not exposed to the organic gas or the like. Consequently, an adherent substance can be inhibited from being formed on a laser emitting facet, and hence the semiconductor laser chip can be inhibited from deterioration. The inventors have found as a result of a deep study that the EVOH is employed as the covering agent in the present invention.

In the aforementioned semiconductor laser apparatus according to the first aspect, the package preferably includes a resin member containing a volatile component, and a surface of the resin member located in the sealed space is preferably covered with the covering agent. According to this structure, the covering agent can effectively block volatile organic gas in the resin member from penetrating into the sealed space of the package. Further, the resin member can be employed in the package, and hence a manufacturing process can be simplified as compared with a case where the package is made of a conventional metal material. Thus, the manufacturing process is simplified, and hence the semiconductor laser apparatus can be inexpensively manufactured.

The aforementioned semiconductor laser apparatus according to the first aspect preferably further comprises a metal plate for mounting the semiconductor laser chip on an inner bottom surface of the package, wherein a surface of the metal plate other than a region on which the semiconductor laser chip is placed is covered with the covering agent. According to this structure, contaminations attached to the surface of the metal plate other than the region on which the semiconductor laser chip is placed in the manufacturing process can also be covered with the covering agent. Thus, the inside of the sealed space of the package can be kept cleaner.

In the aforementioned structure further comprising the metal plate on the inner bottom surface of the package, the package preferably includes a resin member containing a volatile component, and a surface of the resin member located in the sealed space and the surface of the metal plate other than the region on which the semiconductor laser chip is placed are preferably continuously covered with the covering agent. According to this structure, the surfaces of the members constituting the package located in the sealed space are reliably covered with the covering agent with no clearance, and hence the covering agent can reliably block the volatile organic gas from penetrating into the sealed space of the package.

In the aforementioned structure in which the package includes the resin member containing the volatile component, the package preferably includes a base made of resin, mounted with the semiconductor laser chip, and a surface of the base located in the sealed space is preferably covered with the covering agent. According to this structure, the covering agent can effectively block volatile organic gas contained in the base from penetrating into the sealed space of the package. Further, the base can be made of resin, and hence the semiconductor laser apparatus can be inexpensively manufactured.

In the aforementioned structure in which the package includes the base made of resin, the base is preferably made of one of polyamide resin, epoxy resin, polyphenylene sulfide resin, a liquid crystal polymer and photosensitive resin. Even if the base is made of one of the aforementioned resin materials, the covering agent can effectively block the volatile organic gas contained in the base from penetrating into the sealed space of the package. Further, the manufacturing process can be simplified by making the base of one of the aforementioned resin materials as compared with a case where the package is made of a conventional metal material.

The aforementioned semiconductor laser apparatus according to the first aspect preferably further comprises a photodetector arranged in the sealed space, monitoring an intensity of a laser beam from the semiconductor laser chip, wherein the photodetector is fixed through a conductive adhesive layer containing a volatile component in the sealed space, and a surface of the conductive adhesive layer fixing the photodetector exposed in the sealed space is covered with the covering agent. According to this structure, the covering agent can block volatile organic gas from penetrating into the sealed space of the package even if the volatile organic gas is generated from the conductive adhesive layer. Consequently, formation of an adherent substance on a photodetecting surface of the photodetector in addition to the laser emitting facet can be inhibited, and hence output of a laser beam from the semiconductor laser chip can be accurately controlled with this photodetector.

In the aforementioned semiconductor laser apparatus according to the first aspect, the package preferably includes a base mounted with the semiconductor laser chip and a sealing member mounted on the base, and at least a surface of the sealing member located in the sealed space is preferably covered with the covering agent. According to this structure, contaminants or the like attached to the surface of the sealing member on a side of the sealed space are covered with the covering agent, and hence the sealed space of the package can be inhibited from being filled with organic gas generated from these contaminants, and the contaminants can be inhibited from being detached from the surface of the sealing member to fill the sealed space. Further, the strength (rigidity) of the sealing member can be improved by the covering agent provided on the surface (one surface) of the sealing member. Consequently, the sealing member having a prescribed magnitude of rigidity can be easily made even if a low-cost member is employed.

In the aforementioned structure in which the package includes the base and the sealing member, a substantially entire surface of the sealing member on a side bonded to the base including the surface of the sealing member located in the sealed space is preferably covered with the covering agent. According to this structure, the covering agent can be easily formed on one surface (inner surface) of the sealing member in the manufacturing process. Further, the surface of the sealing member located in the sealed space can be reliably covered with the covering agent regardless of a bonding position (mounting method) of the sealing member to the base.

In the aforementioned structure in which the substantially entire surface of the sealing member on the side bonded to the base is covered with the covering agent, the covering agent is preferably arranged on a bonded region of the sealing member and the base. According to this structure, the covering agent is arranged on not only the surfaces located in the sealed space of the package but also the bonded region of the sealing member and the base, and hence the low molecular siloxane, the volatile organic gas or the like existing outside the semiconductor laser apparatus (in the atmosphere) can be effectively inhibited from entering the sealed space of the package through the bonded region of the sealing member and the base.

In this case, the sealing member is preferably bonded to the base with the covering agent arranged on the bonded region of the sealing member and the base. According to this structure, the covering agent can also serve as a bonding member of the sealing member and the base. Further, the EVOH (covering agent) hardly generating the volatile component and having excellent gas barrier properties is employed, dissimilarly to a case where the sealing member and the base are bonded to each other with a general adhesive containing the volatile component, and hence the sealed space of the package can be effectively inhibited from being filled with volatile organic gas.

In the aforementioned structure in which the substantially entire surface of the sealing member on the side bonded to the base is covered with the covering agent, the sealing member is preferably made of metal foil, and substantially entire inner surface of the sealing member made of the metal foil having a side cross section bent in a substantially L-shaped manner from an upper surface to a front surface of the base is preferably covered with the covering agent. According to this structure, the strength (rigidity) of the sealing member can be easily improved by the covering agent provided along the inner surface of the sealing member even if the sealing member is formed by bending the metal foil in a substantially L-shaped manner.

In the aforementioned structure in which the package includes the base and the sealing member, the base preferably has a recess portion provided with an opening from an upper surface to a front surface, and an inner surface of the recess portion and an inner surface of the sealing member are preferably continuously covered with the covering agent. According to this structure, the surfaces of the members constituting the package located in the sealed space are reliably covered with covering agent with no clearance, and hence the covering agent can reliably block volatile organic gas generated outside the package or from the base from penetrating into the sealed space of the package. In the present invention, the “front surface” denotes a side surface on a side where the laser beam emitted from the semiconductor laser chip is emitted outward.

In the aforementioned structure in which the package includes the base and the sealing member, the sealing member is preferably made of elastic resin, the package is preferably sealed by fitting the base and the sealing member into each other, and surfaces of the base and the sealing member exposed in the sealed space are preferably covered with the covering agent. According to this structure, the base and the sealing member can be easily brought into close contact with each other, and hence the package can be easily sealed. In other words, it is not necessary to employ an additional adhesive or the like for sealing, and hence generation of organic gas can be inhibited.

In this case, the sealing member is preferably cylindrically formed with a bottom portion, a cylindrical inner peripheral surface of the sealing member is preferably circularly fitted into an outer peripheral surface of the base, and the covering agent is preferably arranged on a region in which the base and the sealing member are circularly fitted into each other in addition to the surfaces of the base and the sealing member exposed in the sealed space. According to this structure, the covering agent is arranged on not only the surfaces located in the sealed space of the package but also the bonded region of the sealing member and the base, and hence the low molecular siloxane, the volatile organic gas or the like existing outside the semiconductor laser apparatus (in the atmosphere) can be reliably inhibited from entering the sealed space of the package through the bonded region of the sealing member and the base.

In the aforementioned semiconductor laser apparatus according to the first aspect, the package preferably includes a sealing member mounted on the base and a window member transmitting a laser beam emitted from the semiconductor laser chip to an outside of the package, and the window member is preferably bonded to the sealing member with the covering agent arranged on a surface of the sealing member other than an opening formed in the sealing member. According to this structure, the package can be easily sealed with the window member for emitting the laser beam without harmful effects such as contact of the laser beam with the covering agent.

In the aforementioned semiconductor laser apparatus according to the first aspect, a gas absorbent is preferably set in the sealed space of the package. According to this structure, even if the low molecular siloxane, the volatile organic gas or the like existing outside the semiconductor laser apparatus (in the atmosphere) penetrates into the sealed space, it can be easily absorbed by the gas absorbent. Thus, a concentration of organic gas or the like in the sealed space of the package can be reduced.

In this case, the gas absorbent is preferably sandwiched in contact with the covering agent in the sealed space to be fixed. According to this structure, the gas absorbent set in the sealed space can be prevented from easily moving in the sealed space, and hence contact of the laser beam from the semiconductor laser chip with the gas absorbent can be easily prevented.

In the aforementioned semiconductor laser apparatus according to the first aspect, the semiconductor laser chip preferably includes a nitride-based semiconductor laser chip. In the nitride-based semiconductor laser chip having a short lasing wavelength and requiring a higher output power, an adherent substance is easily formed on a laser emitting facet thereof, and hence the use of the aforementioned “covering agent” in the present invention is highly effective in inhibiting deterioration of the nitride-based semiconductor laser chip.

An optical apparatus according to a second aspect of the present invention comprises a semiconductor laser apparatus including a package constituted by a plurality of members, having sealed space inside and a semiconductor laser chip arranged in the sealed space, and an optical system controlling a beam emitted from the semiconductor laser apparatus, wherein surfaces of the members located in the sealed space are covered with a covering agent made of EVOH.

In the optical apparatus according to the second aspect of the present invention, the semiconductor laser apparatus is formed as described above, and hence the optical apparatus mounted with the semiconductor laser apparatus in which the semiconductor laser chip is inhibited from deterioration can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view of a semiconductor laser apparatus according to a first embodiment of the present invention in which a base and a sealing member are separated from each other;

FIG. 2 is a longitudinal sectional view taken along the center line of the semiconductor laser apparatus according to the first embodiment of the present invention in a width direction;

FIGS. 3 and 4 are top plan views for illustrating a manufacturing process of the semiconductor laser apparatus according to the first embodiment of the present invention;

FIGS. 5 to 7 are perspective views for illustrating the manufacturing process of the semiconductor laser apparatus according to the first embodiment of the present invention;

FIG. 8 is a longitudinal sectional view taken along the center line of a semiconductor laser apparatus according to a modification of the first embodiment of the present invention in a width direction;

FIG. 9 is an exploded perspective view of a semiconductor laser apparatus according to a second embodiment of the present invention in which a base and a sealing member are separated from each other;

FIG. 10 is a longitudinal sectional view taken along the center line of the semiconductor laser apparatus according to the second embodiment of the present invention in a width direction;

FIG. 11 is an exploded perspective view of a semiconductor laser apparatus according to a third embodiment of the present invention in which a base and a cap are separated from each other;

FIG. 12 is a longitudinal sectional view taken along the center line of the semiconductor laser apparatus according to the third embodiment of the present invention in a width direction;

FIG. 13 is a longitudinal sectional view taken along the center line of a semiconductor laser apparatus according to a modification of the third embodiment of the present invention in a width direction;

FIG. 14 is an exploded perspective view of a semiconductor laser apparatus according to a fourth embodiment of the present invention in which a cap and a base are separated from each other;

FIG. 15 is a longitudinal sectional view taken along the center line of the semiconductor laser apparatus according to the fourth embodiment of the present invention in a width direction;

FIGS. 16 and 17 are sectional views for illustrating a manufacturing process of a cap of the semiconductor laser apparatus according to the fourth embodiment of the present invention;

FIG. 18 is a sectional view for illustrating a manufacturing process of a cap of a semiconductor laser apparatus according to a modification of the fourth embodiment of the present invention;

FIG. 19 is a longitudinal sectional view showing a structure of a semiconductor laser apparatus according to a fifth embodiment of the present invention;

FIG. 20 is a top plan view showing the structure of the semiconductor laser apparatus according to the fifth embodiment of the present invention;

FIGS. 21 to 23 are sectional views for illustrating a manufacturing process of the semiconductor laser apparatus according to the fifth embodiment of the present invention;

FIG. 24 is a top plan view of a three-wavelength semiconductor laser apparatus according to a sixth embodiment of the present invention, from which a sealing member is removed; and

FIG. 25 is a schematic diagram showing a structure of an optical pickup comprising the three-wavelength semiconductor laser apparatus according to the eighth embodiment of the present invention.

### DESCRIPTION OF THE PREFERRED EMBODIMENTS

Embodiments of the present invention are hereinafter described with reference to the drawings.

### First Embodiment

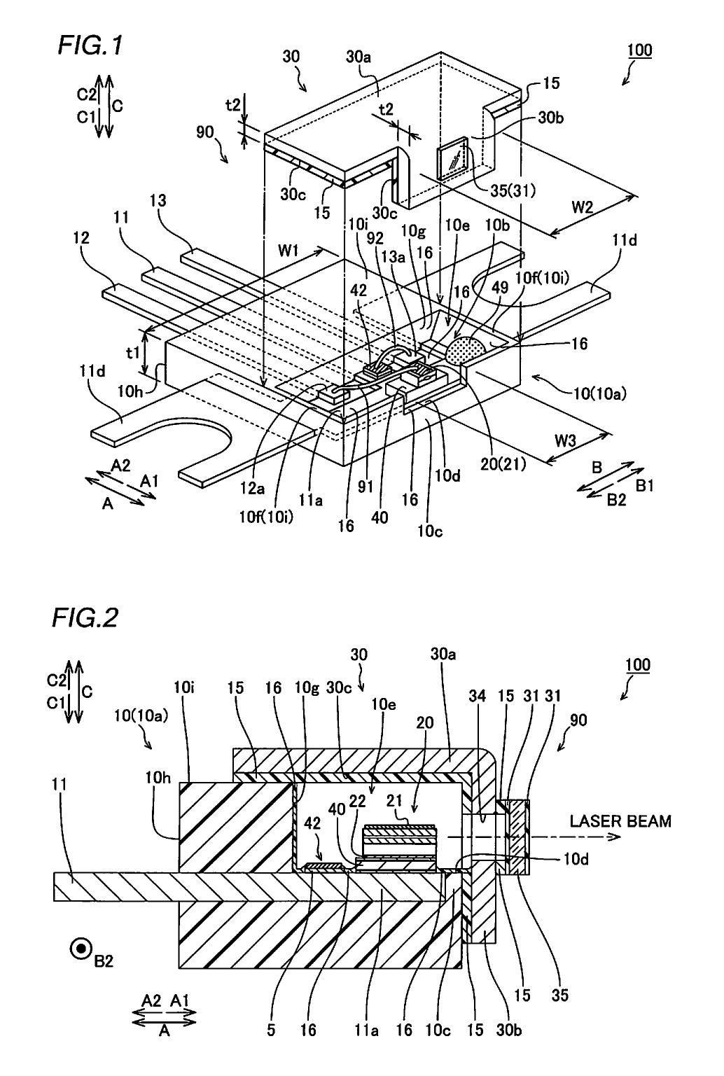

A structure of a semiconductor laser apparatus 100 according to a first embodiment of the present invention is now described with reference to FIGS. 1 and 2.

The semiconductor laser apparatus 100 according to the first embodiment of the present invention comprises a blue-violet semiconductor laser chip 20 having a lasing wavelength of about 405 nm and a package 90 sealing the blue-violet semiconductor laser chip 20. The package 90 has a base 10 mounted with the blue-violet semiconductor laser chip 20 and a sealing member 30 mounted on the base 10, covering the blue-violet semiconductor laser chip 20 from two directions, that is, from upper (a C2 side) and front (an A1 side) sides. The blue-violet semiconductor laser chip 20 is an example of the “semiconductor laser chip” in the present invention.

The base 10 has a tabular base body 10a with a thickness t1 (in a direction C) made of polyamide resin, as shown in FIG. 1. A recess portion 10b recessed by a depth about half the thickness t1 downward (to a C1 side) is formed in about half a front region of the base body 10a. A front wall portion 10c of the base body 10a on the front side is provided with a substantially rectangular opening 10d having a width W3 on the central portion in a width direction (direction B). Therefore, the recess portion 10b is arranged with a substantially rectangular opening 10e, which opens in an upper surface 10i, and the opening 10d, which opens on the front side. The recess portion 10b is constituted by the front wall portion 10c, a pair of side wall portions 10f extending substantially parallel to each other backward (to an A2 side) from both side ends of the front wall portion 10c, an inner wall portion 10g connecting back ends (on the A2 side) of the side wall portions 10f and a bottom surface connecting the front wall portion 10c, the pair of side wall portions 10f and the inner wall portion 10g on the lower portion.

In the base 10, lead frames 11, 12 and 13 made of metal are so arranged as to pass through the base body 10a from the front side to the back side in a state of being isolated from each other. In plan view, the lead frame 11 passes through a substantially central portion of the base body 10a in the direction B while the lead frames 12 and 13 are arranged on the outer sides (a B2 side and a B1 side) of the lead frame 11 in the width direction. Back end regions of the lead frames 11, 12 and 13, extending backward are exposed from a back wall portion 10h of the base body 10a at the back. The lead frame 11 is an example of the “metal plate” in the present invention.

Front end regions 11a, 12a and 13a of the lead frames 11, 12 and 13 at the front are exposed from the inner wall portion 10g of the base body 10a, and the front end regions 11a to 13a are arranged on the bottom surface of the recess portion 10b. The front end region 11a of the lead frame 11 widens in the direction B on the bottom surface of the recess portion 10b. The bottom surface of the recess portion 10b is an example of the “inner bottom surface of the package” in the present invention.

The lead frame 11 is integrally formed with a pair of heat radiation portions 11d connected to the front end region 11a. The pair of heat radiation portions 11d are arranged substantially symmetrically about the lead frame 11 on both sides in the direction B. The heat radiation portions 11d extend from the front end region 11a and pass through side surfaces of the base body 10a in directions B1 and B2 to be exposed. Therefore, heat generated by the operating blue-violet semiconductor laser chip 20 is transferred to a submount 40 and the heat radiation portions 11d on both sides to be radiated to the outside of the semiconductor laser apparatus 100.

The sealing member 30 is made of aluminum foil. The sealing member 30 has a ceiling surface portion 30a with a thickness t2 of about 50 μm and a width W1 (in the direction B) and a front surface portion 30b with a thickness t2 and a width W2 (W2 W1) bent at an end of the ceiling surface portion 30a on one side (A1 side) and extending downward, as shown in FIG. 1. The ceiling surface portion 30a and the front surface portion 30b are formed in a state of being substantially orthogonal to each other, whereby a side cross section of the sealing member 30 in a direction A is substantially L-shaped. The width W2 of the front surface portion 30b is larger than an opening length W3 of the opening 10d in the direction B (W2>W3).

As shown in FIG. 2, a sealant 15 with a thickness t3 of about 0.2 mm is applied to a substantially entire region on an inner surface 30c becoming a back surface of the sealing member 30. Eval (registered trademark, Eval F104B manufactured by Kuraray Co., Ltd.) which is EVOH resin is employed as the sealant 15. The EVOH resin is a material having excellent gas barrier properties and mainly applied to a food wrapper and so on as a multilayered film.

A hole 34 (window portion) penetrating through the sealing member 30 in a thickness direction is provided in a substantially central portion of the front surface portion 30b. A light transmission portion 35 having translucence, made of borosilicate glass with a thickness of about 0.25 mm is provided to cover the hole 34 from the outside (A1 side) of the front surface portion 30b. The light transmission portion 35 is bonded onto the front surface portion 30b through the sealant 15 with a thickness of about 0.1 mm applied onto an outer surface of the front surface portion 30b other than the hole 34. Therefore, the hole 34 is completely closed by the light transmission portion 35 mounted through the sealant 15. A covering agent 16 is not applied onto the light transmission portion 35, and dielectric films 31 of Al₂O₃ are formed on surfaces of the light transmission portion 35 on the A1 and A2 sides. The hole 34 is an example of the “opening” in the present invention. The light transmission portion 35 is an example of the “window member” in the present invention.

In this state, the sealing member 30 and the base 10 are bonded to each other through the sealant 15. In other words, the sealing member 30 is mounted on the base 10 through the sealant 15 in the periphery (a region near the inner wall portion 10g and respective upper surfaces of the pair of side wall portions 10f and the front wall portion 10c) of the opening 10e in the upper surface 10i and the periphery of the opening 10d in the front surface (an outer surface (on the A1 side) of the front wall portion 10c). In other words, the sealing member 30 is bonded to the base 10 with the sealant 15 also serving as the “covering agent” in the present invention arranged on a bonded region of the sealing member 30 and the base 10. The aforementioned bonded region with the sealant 15 is annularly formed to have continuity. Thus, the openings 10d and 10e are completely closed by the sealing member 30, and the blue-violet semiconductor laser chip 20 is sealed with the package 90. Therefore, in the semiconductor laser apparatus 100, an adherent substance or the like caused by a volatile component is not generated or hardly generated on a light-emitting surface in the package 90.

The blue-violet semiconductor laser chip 20 is mounted on a substantially central portion of an upper surface of the front end region 11a of the lead frame 11 through the submount 40 having conductivity.

The blue-violet semiconductor laser chip 20 is mounted in a junction-up system such that the light-emitting surface faces forward. In a pair of cavity facets formed on the blue-violet semiconductor laser chip 20, that emitting a laser beam having relatively large light intensity serves as the light-emitting surface and that having relatively small light intensity serves as a light-reflecting surface. The blue-violet semiconductor laser chip 20 emits the laser beam in a direction A1. A dielectric multilayer film (not shown) made of an AlN film, an Al₂O₃ film or the like is formed on the light-emitting surface and the light-reflecting surface of the blue-violet semiconductor laser chip 20 by facet coating treatment in a manufacturing process.

A first end of a metal wire 91 made of Au or the like is bonded to a p-side electrode 21 formed on an upper surface of the blue-violet semiconductor laser chip 20, and a second end of the metal wire 91 is connected to the front end region 12a. An n-side electrode 22 formed on a lower surface of the blue-violet semiconductor laser chip 20 is electrically connected to the front end region 11a through the submount 40.

A photodiode (PD) 42 employed to monitor an intensity of a laser beam is arranged on a side of the light-reflecting surface of the blue-violet semiconductor laser chip 20 in a back portion of the submount 40 such that a photodetecting surface faces upward. A lower surface (n-type region) of the tabular PD 42 is electrically connected to the front end region 11a through a conductive adhesive layer 5 made of resin paste (Ag paste or the like) containing a volatile component. A first end of a metal wire 92 made of Au or the like is bonded to an upper surface (p-type region) of the PD 42, and a second end of the metal wire 92 is connected to the front end region 13a. The photodiode (PD) 42 is an example of the “photodetector” in the present invention.

As shown in FIGS. 1 and 2, a covering agent 16 made of EVOH resin is applied with a prescribed thickness onto a surface of each member located in sealed space (closed space surrounded by the base 10 and the sealing member 30) of the package 90. Specifically, the covering agent 16 continuously covers an inner surface (inner surfaces of the front wall portion 10c, the pair of side wall portions 10f and the inner wall portion 10g and a bottom surface of the recess portion 10b) of the recess portion 10b, a surface of the front end region 11a other than portions onto which the submount 40 and the PD 42 are bonded and surfaces of the front end regions 12a and 13a with no clearance. At this time, a surface of the conductive adhesive layer 5 protruding from a lower portion of the PD 42 is also covered with the covering agent 16. The sealant 15 exposed in the sealed space of the package 90 of the sealant 15 applied onto the inner surface 30c also serves as the “covering agent” in the present invention. Therefore, the base body 10a of resin, the lead frames 11 to 13 and the inner surface 30c of the sealing member 30 located in the sealed space of the package 90 are completely covered with the “covering agent” in the present invention.

As shown in FIG. 1, a gas absorbent 49 made of silica gel is provided on the front end region 11a on a side (B1 side) of the submount 40 in the package 90 through the covering agent 16. The gas absorbent 49 is formed substantially in the form of a hemisphere having a bottom surface underneath, and a height from the bottom surface to a top of a spherical surface is slightly smaller than the depth (t1/2) of the recess portion 10b. Thus, the gas absorbent 49 is fixed in the recess portion 10b in a state of being sandwiched between the front end region 11a and the sealant 15 on the back surface (inner surface 30c) of the sealing member 30 and adhering thereto, as described later. The semiconductor laser apparatus 100 is constituted in the aforementioned manner.

A manufacturing process of the semiconductor laser apparatus 100 according to the first embodiment is now described with reference to FIGS. 1 to 7.

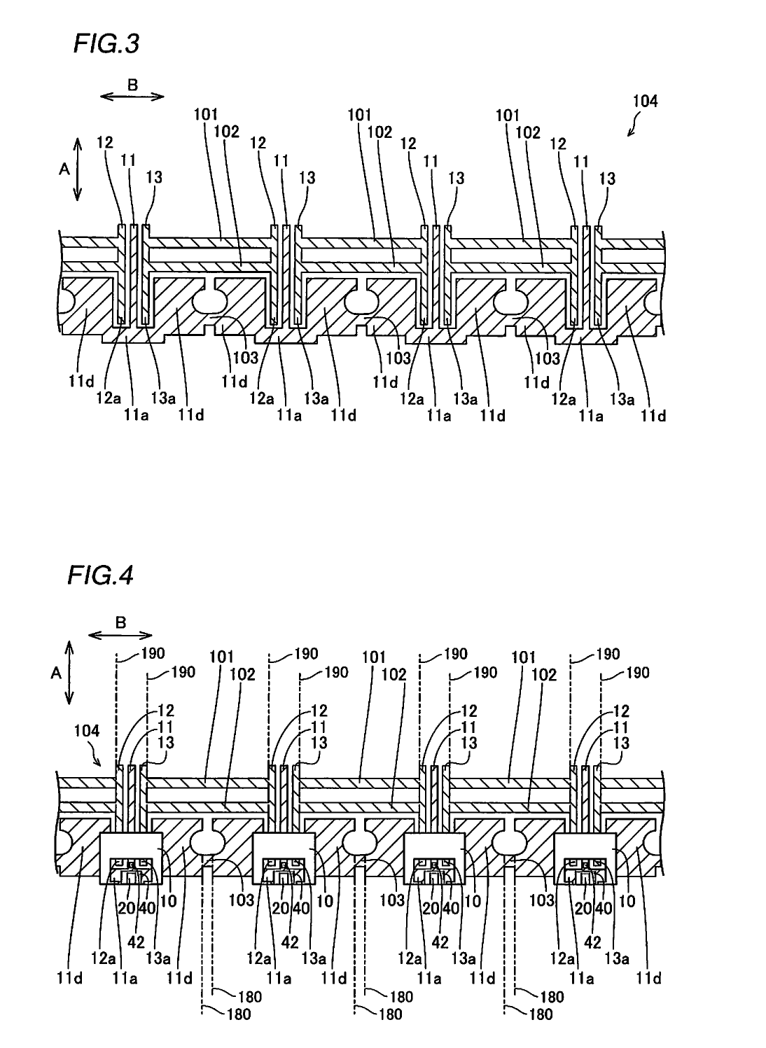

As shown in FIG. 3, a metal plate made of a strip-shaped thin plate of iron, copper or the like is first etched, thereby forming a lead frame 104 in which the lead frame 11 having the heat radiation portions 11d formed integrally with the front end region 11a and the lead frames 12 and 13 arranged on both sides of the lead frame 11 are repeatedly patterned laterally (in the direction B). At this time, the lead frames 12 and 13 are patterned in a state of being coupled by coupling portions 101 and 102 extending laterally. The heat radiation portions 11d are patterned in a state of being coupled by a coupling portion 103 extending laterally.

Thereafter, the base 10 (see FIG. 1) having the base body 10a through which a set of the lead frames 11 to 13 passes and the recess portion 10b with the bottom surface on which the front end regions 11a to 13a of the respective frames are exposed is molded into the lead frame 104 by a resin molding apparatus, as shown in FIG. 4. At this time, the base body 10a is so molded that the front end regions 11a to 13a of the lead frames 11 to 13 are arranged in the recess portion 10b.

The blue-violet semiconductor laser chip 20, the PD 42 and the submount 40 are prepared through prescribed manufacturing processes. Then, the blue-violet semiconductor laser chip 20 is bonded onto one surface (upper surface) of the submount 40 with a conductive adhesive layer (not shown). At this time, the n-side electrode 22 is bonded onto the upper surface of the submount 40.

Thereafter, the submount 40 is bonded onto the substantially central portion (in a lateral direction) of the upper surface of the front end region 11a through a conductive adhesive layer (not shown), as shown in FIG. 4. At this time, a lower surface of the submount 40 to which the blue-violet semiconductor laser chip 20 is not bonded is bonded onto the upper surface of the front end region 11a. Then, the lower surface of the PD 42 is bonded onto a region at the rear of the submount 40 and between the front end region 11a and the inner wall portion 10g with the conductive adhesive layer 5. At this time, the n-type region of the PD 42 is bonded to the lead frame 11.

Thereafter, the p-side electrode 21 and the front end region 12a are connected with each other through the metal wire 91, as shown in FIG. 1. The p-type region (upper surface) of the PD 42 and the front end region 13a are connected with each other through the metal wire 92.

Then, the covering agent 16 is applied to continuously cover the inner surface (the inner surfaces of the front wall portion 10c, the pair of side wall portions 10f and the inner wall portion 10g and the bottom surface of the recess portion 10b) of the recess portion 10b, the surface of the front end region 11a other than the portions onto which the submount 40 and the PD 42 are bonded and the surfaces of the front end regions 12a and 13a in a state where the base 10 is heated to about 230° C. Thus, the covering agent 16 is also applied to the vicinities of the ends of the metal wires 91 and 92 on sides of the lead frames.

After cooling the base 10, the lead frame 104 is cut along division lines 180 and 190, as shown in FIG. 4, thereby cutting and removing the coupling portions 101, 102 and 103. Thereafter, the gas absorbent 49 is placed on the front end region 11a on the side (B1 side) of the submount 40. At this time, the gas absorbent 49 is placed with the flat bottom surface down in a state where the top of the spherical surface is slightly smaller than the opening 10e (upper surface 10i).

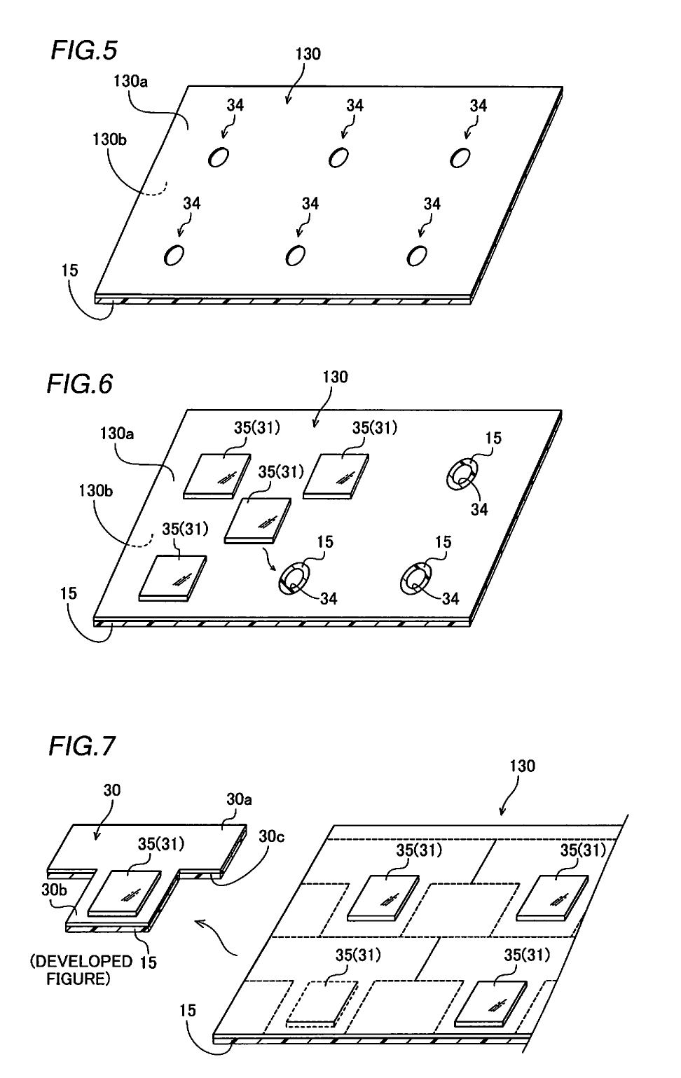

Meanwhile, as shown in FIG. 5, the sealant 15 is applied with a thickness of about 0.2 mm onto an entire back surface 130b in a state where a sheet-like aluminum foil 130 having a thickness of about 17 μm is heated to about 220° C. Thereafter, a plurality of the holes 34 are formed in prescribed regions of the aluminum foil 130 at prescribed intervals.

Thereafter, the sealant 15 is annularly applied to the periphery of the hole 34 on an upper surface 130a of the aluminum foil 130 heated to about 220° C., as shown in FIG. 6. In a state where the sealant 15 is melted by heat, the light transmission portion 35 formed in a substantially disc shape and formed with the dielectric films 31 is press-bonded to close the hole 34. Thereafter, the aluminum foil 130 is cooled thereby bonding the light transmission portion 35 onto the aluminum foil 130 through the sealant 15. The sealant 15 applied onto the back surface 130b is also hardened by cooling, and hence a prescribed magnitude of rigidity is produced in the plate-like sealing member 30. Then, the aluminum foil 130 is cut in a shape of the sealing member 30 developed on a plane surface, as shown in FIG. 7.

Thereafter, the unbent sealing member 30 is thermocompression bonded onto an upper surface of the base 10 in a state where the base 10 is heated to about 220° C., and the sealing member 30 is thermocompression bonded onto a front surface of the front wall portion 10c while bending the sealing member 30 along the front wall portion 10c such that the front surface portion 30b is perpendicular to the ceiling surface portion 30a. In the sealing member 30, the sealant 15 starts to melt by surrounding heat, and hence the aluminum foil 130 is rendered deformable. Then, the base 10 is cooled thereby mounting the sealing member 30 on the base 10. When mounting the sealing member 30, the melted sealant 15 on the front end region 11a and the back surface of the sealing member 30 comes into contact with the gas absorbent 49, and hence the gas absorbent 49 can be adhered to the sealant 15 on the front end region 11a and the back surface of the sealing member 30 after cooling. Thus, the sealing member 30 is formed in a shape shown in FIG. 2. The semiconductor laser apparatus 100 is formed in the aforementioned manner.

According to the first embodiment, as hereinabove described, surfaces of the resin base body 10a, the outer periphery of the PD 42, the metal lead frames 11 to 13 and so on located in the sealed space (closed space surrounded by the base 10 and the sealing member 30) of the package 90 are completely covered with the covering agent 16 made of the EVOH resin. Thus, the covering agent 16 can block volatile organic gas from penetrating into the sealed space of the package 90 even if the volatile organic gas is generated from a material (polyamide resin) of the base 10, the conductive adhesive layer 5 (Ag paste) or the like. Further, even if low molecular siloxane, volatile organic gas or the like existing outside the semiconductor laser apparatus 100 (in the atmosphere) penetrates into the components of the package 90, the covering agent 16 can inhibit the low molecular siloxane, the volatile organic gas or the like from entering the package 90. Further, the EVOH resin hardly generates the aforementioned volatile component, and hence the semiconductor laser chip 20 in the package 90 is not exposed to the organic gas or the like. Consequently, the adherent substance can be inhibited from being formed on a laser emitting facet, and hence the semiconductor laser chip 20 can be inhibited from deterioration. Especially in the blue-violet semiconductor laser chip 20 having a short lasing wavelength and requiring a higher output power, an adherent substance is easily formed on a laser emitting facet thereof, and hence the use of the covering agent 16 is highly effective.

The base 10 is made of polyamide resin, whereby the manufacturing process can be simplified as compared with a case where the package is made of a conventional metal material. The semiconductor laser apparatus 100 can be inexpensively manufactured due to a reduced material cost and the simplified manufacturing process.

A surface of the front end region 11a of the lead frame 11 other than a region onto which the submount 40 mounted with the blue-violet semiconductor laser chip 20 is bonded is covered with the covering agent 16. Thus, contaminations attached to the surface of the front end region 11a other than the region onto which the submount 40 is bonded in the manufacturing process can also be covered with the covering agent 16. Thus, the inside of the sealed space of the package 90 can be kept cleaner.

The covering agent 16 continuously covers the inner surface (the inner surfaces of the front wall portion 10c, the pair of side wall portions 10f and the inner wall portion 10g and the bottom surface of the recess portion 10b) of the recess portion 10b, the surface of the front end region 11a other than the portions onto which the submount 40 and the PD 42 are bonded and the surfaces of the front end regions 12a and 13a. Thus, the surfaces of the members constituting the package 90 located in the sealed space are reliably covered with the covering agent 16 with no clearance, and hence the covering agent 16 can reliably block the volatile organic gas from penetrating into the package 90.

A surface of the conductive adhesive layer 5 fixing the PD 42 exposed in the sealed space is covered with the covering agent 16, and hence the covering agent 16 can block volatile organic gas from penetrating into the package 90 even if the volatile organic gas is generated from the conductive adhesive layer 5 of Ag paste or the like. Consequently, formation of an adherent substance on the photodetecting surface (p-type region) of the PD 42 in addition to the laser emitting facet of the blue-violet semiconductor laser chip 20 can be inhibited, and hence output of the laser beam from the blue-violet semiconductor laser chip 20 can be accurately controlled with the PD 42.

The sealant 15 made of the EVOH resin is formed on the entire inner surface 30c. In this case, the substantially entire inner surface 30c of the sealing member 30 made of the aluminum foil having a side cross section bent in a substantially L-shaped manner from the upper surface 10i of the base 10 to the front wall portion 10c is covered with the sealant 15. Thus, contaminants or the like attached to the surface (inner surface 30c) of the sealing member 30 on a side of the sealed space are covered with the sealant 15, and hence the sealed space of the package 90 can be inhibited from being filled with organic gas generated from these contaminants, and the contaminants can be inhibited from being detached from the surface of the sealing member 30 to fill the sealed space. Further, the physical strength (rigidity) is increased by the sealant 15 provided on the entire inner surface 30c even if the sealing member 30 is made of the aluminum foil 130 in the form of a thin film normally insufficient for the component of the package 90. Consequently, the sealing member 30 having a prescribed magnitude of rigidity can be easily made even if a low-cost metal foil is employed. Further, unnecessary deformation in the manufacturing process can be prevented by increasing the rigidity. Further, handling in the manufacturing process becomes easier.

The base 10, the sealing member 30 and the light transmission portion 35 are bonded to each other through the sealant 15 made of the EVOH resin. This resin material with excellent gas barrier properties can inhibit low molecular siloxane, volatile organic gas or the like existing outside the semiconductor laser apparatus 100 (in the atmosphere) from penetrating into the sealant 15 and entering the package 90. Consequently, the blue-violet semiconductor laser chip 20 can be further inhibited from deterioration.

The light transmission portion 35 is mounted on the sealing member 30 through the sealant 15. In other words, the light transmission portion 35 and the sealing member 30 are bonded to each other with the sealant 15 without employing an adhesive such as an acrylic resin adhesive or an epoxy resin adhesive, and hence the blue-violet semiconductor laser chip 20 sealed in the package 90 is not exposed to organic gas generated by the adhesive. Therefore, the blue-violet semiconductor laser chip 20 can be effectively inhibited from deterioration.

The light transmission portion 35 is bonded to the sealing member 30 with the sealant 15 arranged on the front surface portion 30b other than the hole 34 (window portion) formed in the sealing member 30. Thus, the package 90 can be easily sealed with the light transmission portion 35 for emitting the laser beam without harmful effects such as contact of the laser beam with the sealant 15.

The aforementioned sealant 15 made of the EVOH resin is a resin material having a property of melting by heat (about 220° C.), and hence the sealant 15 can be easily applied to a bonded portion of the sealing member 30 and the light transmission portion 35 and a bonded portion of the sealing member 30 and the base 10. The aforementioned members can be easily bonded to each other by hardening of the sealant 15 following removal of heat (cooling). Thus, the package 90 can be sealed by bonding the base 10, the sealing member 30 and the light transmission portion 35 to each other without requiring a complicated manufacturing process.

In order to confirm usefulness of employing the EVOH resin as the sealant 15 and the covering agent 16, the following experiment was performed. First, the blue-violet semiconductor laser chip 20 was mounted on a metal stem (base) having a diameter (outer diameter) of 9 mm, and in a state where a pellet of the EVOH resin cut to weigh about 5 mg was put on an inner surface of a metal cap (with a glass window), the stem was sealed with the cap. Then, an operation test was performed by emitting a laser beam adjusted to 10 mW output power by Automatic Power Control (APC) from the blue-violet semiconductor laser chip 20 for 250 hours under a condition of 70° C. Consequently, an operating current of a semiconductor laser apparatus did not remarkably change even after 250 hours. As a comparative example, an operation test was performed in a semiconductor laser apparatus having the semiconductor laser chip sealed without putting the EVOH resin on the inner surface of the cap. The operating current was not remarkably different from that in the comparative example after 250 hours. From these results, it has been confirmed that the EVOH resin hardly generates organic gas or the like, and usefulness of employing the EVOH resin as the sealant 15 and the covering agent 16 has been confirmed.

The sealing member 30 is mounted on the base 10 to cover the semiconductor laser chip, and the sealing member 30 and the light transmission portion 35 are bonded to each other through the sealant 15. Thus, a bonding state of the sealant 15 can be confirmed through the light transmission portion 35 having translucence when the sealing member 30 and the light transmission portion 35 are bonded to each other with the sealant 15, and hence the sealing member 30 and the light transmission portion 35 can be reliably bonded to each other without formation of air bubbles in the sealant 15. Consequently, adhesiveness between the sealing member 30 and the light transmission portion 35 in the bonded portion can be increased. The light transmission portion 35 is provided at a position separated from the metal wires 91 and 92, and hence the light transmission portion 35 is hardly influenced by heat generated in melting solder of the metal wires 91 and 92. Considering that the EVOH resin has thermoplasticity, the use of the sealant 15 in the present invention for bonding the light transmission portion 35 insusceptible to heat is effective.

The sealing member 30 and the light transmission portion 35 are thermocompression bonded to each other with the sealant 15, and thereafter the sealing member 30 and the base 10 are thermocompression bonded to each other with the sealant 15. In other words, the sealant 15 made of the EVOH resin, handling of which is easy in the manufacturing process, is employed in the manufacturing process of the semiconductor laser apparatus 100, and hence the package 90 can be sealed by bonding the base 10, the sealing member 30 and the light transmission portion 35 to each other without requiring a complicated manufacturing process.

The gas absorbent 49 is provided in the package 90, whereby volatile organic gas generated by the base body 10a can be absorbed by the gas absorbent 49. Thus, a concentration of organic gas in the package 90 can be reduced. Consequently, the blue-violet semiconductor laser chip 20 can be more reliably inhibited from deterioration.

The gas absorbent 49 is sandwiched in contact with the covering agent 16 on the front end region 11a and the sealant 15 on the inner surface 30c of the sealing member 30 in the sealed space (recess portion 10b) to be fixed. Thus, the gas absorbent 49 can be prevented from easily moving in the sealed space, and hence contact of the laser beam from the blue-violet semiconductor laser chip 20 with the gas absorbent 49 can be easily prevented.

### Modification of First Embodiment

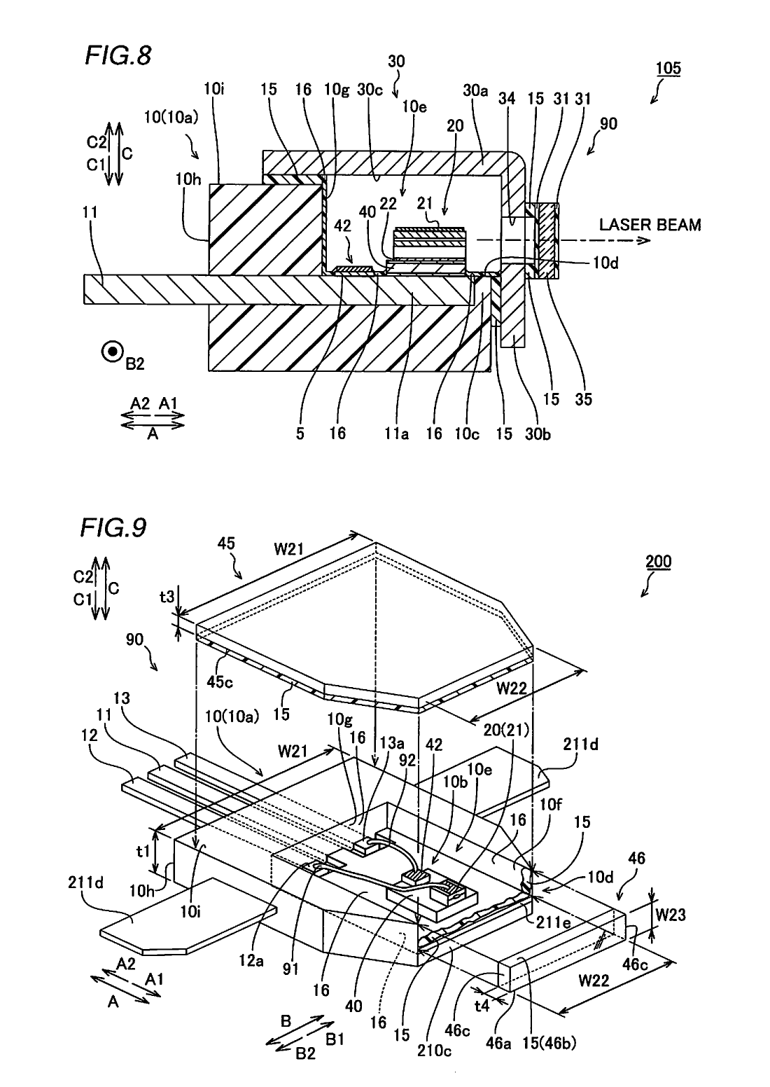

A semiconductor laser apparatus 105 according to a modification of the first embodiment is now described. In this semiconductor laser apparatus 105, a sealing member 30 is made of aluminum foil with a thickness of about 50 μm, as shown in FIG. 8. At this time, a sealant 15 is not applied onto an inner surface 30c of the sealing member 30 located in sealed space of a package 90, and a surface of the aluminum foil is exposed in the sealed space. On the other hand, the sealant 15 is applied with a prescribed thickness onto a peripheral region (a region near an inner wall portion 10g and respective upper surfaces of a pair of side wall portions 10f and a front wall portion 10c) of an opening 10e in an upper surface 10i of a base body 10a and a peripheral region of an opening 10d in the front surface (an outer surface (on an A1 side) of the front wall portion 10c) so as to surround the peripheries of the openings 10e and 10d shown in FIG. 1. In this state, the sealing member 30 is mounted on a base 10 by bringing the vicinity of an outer edge of the inner surface 30c of a ceiling surface portion 30a and a front surface portion 30b into close contact with the sealant 15. The remaining structure of the semiconductor laser apparatus 105 according to the modification of the first embodiment is substantially similar to that of the semiconductor laser apparatus 100 according to the first embodiment and denoted by the same reference numerals in the figure.

In a manufacturing process of the semiconductor laser apparatus 105, a light transmission portion 35 is bonded onto an aluminum foil 130 (see FIG. 5) having a lower surface 130b onto which the sealant 15 is not applied, similarly to the first embodiment. After the sealing member 30 similar to that of the first embodiment is prepared, the front surface portion 30b is bent in a direction perpendicular to the ceiling surface portion 30a such that the light transmission portion 35 is located outside. Thus, the sealing member 30 is previously formed in a shape shown in FIG. 8 before the same is thermocompression bonded to the base 10, dissimilarly to the first embodiment.

Thereafter, the sealant 15 continuously covering the periphery (the region near the inner wall portion 10g and the respective upper surfaces of the pair of side wall portions 10f and the front wall portion 10c) of the opening 10e in the upper surface 10i and the periphery of the opening 10d in the front surface (the outer surface of the front wall portion 10c) is so applied as to surround the peripheries of the openings 10e and 10d of the base 10 in a state where the base 10 is heated to about 220° C. In a state where the sealant 15 is melted by heat, the sealing member 30 is thermocompression bonded to the base 10. Thereafter, the base 10 is cooled, whereby the sealing member 30 is mounted on the base 10.

The remaining manufacturing process is substantially similar to that of the first embodiment. The effects of the modification of the first embodiment are similar to those of the first embodiment.

### Second Embodiment

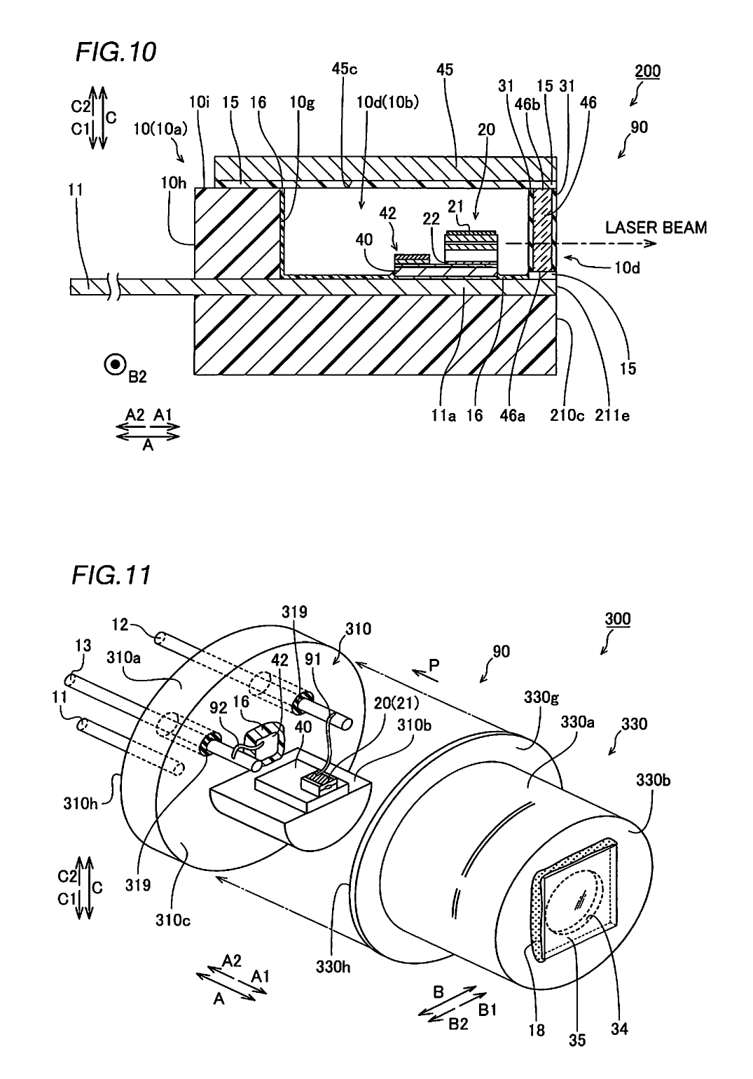

A semiconductor laser apparatus 200 according to a second embodiment of the present invention is now described. In this semiconductor laser apparatus 200, as shown in FIGS. 9 and 10, a package 90 has a base 10, and a sealing member 45 and a window member 46 both mounted on the base 10, covering a blue-violet semiconductor laser chip 20 from upper (a C2 side) and front (an A1 side) sides, respectively. While a gas absorbent 49 (see FIG. 1) is not provided in a recess portion 10b in the semiconductor laser apparatus 200, the gas absorbent 49 may be provided in the recess portion 10b.

The sealing member 45 is made of Cu alloy foil such as nickel silver with a thickness t3 of about 15 μm. The sealing member 45 has a planar shape substantially identical to a planar shape of a base body 10a, and a width W21 at the back and a width W22 at the front. A sealant 15 having a thickness of about 0.2 mm is applied onto a substantially entire region of a back surface 45c of the sealing member 45.

The window member 46 is made of a tabular glass plate of borosilicate glass (hard glass). The window member 46 has a thickness t4 (in a direction A) of about 0.25 mm, a width W22 (in a direction B) and a height W23 (in a direction C) substantially equal to a depth (t1/2) of the recess portion 10b and is mounted in an opening 10d. At this time, the sealant 15 continuously covering an inner surface of the opening 10d (an upper surface of a front end region 11a of a lead frame 11 in the opening 10d and respective inner surfaces of a pair of side wall portions 10f) is applied with a prescribed thickness between the window member 46 and the base body 10a. In this state, the window member 46 is mounted while bringing a lower surface 46a and both side surfaces 46c into close contact with the sealant 15. Dielectric films 31 are formed on surfaces (on A1 and A2 sides) of the window member 46.

Then, the sealing member 45 is mounted on the base 10 from an upper side of an opening 10e. In other words, the sealing member 45 is mounted on the base 10 through the sealant 15 in an upper surface 10i (a region near an inner wall portion 10g and respective upper surfaces of the pair of side wall portions 10f) of the base body 10a and an upper surface 46b of the window member 46. Heat radiation portions 211d are provided on back regions of the base body 10a.

A PD 42 is arranged on a side of a light-reflecting surface of the blue-violet semiconductor laser chip 20 in a back portion (on the A2 side) of a submount 40 such that a photodetecting surface faces upward (in a direction C2). A lower surface (n-type region) of the PD 42 is electrically connected to the submount 40. The remaining structure of the semiconductor laser apparatus 200 is substantially similar to that of the semiconductor laser apparatus 100 according to the first embodiment and denoted by the same reference numerals in the figures.

In a manufacturing process of the semiconductor laser apparatus 200, a lead frame in which the heat radiation portions 211d are repeatedly patterned together with lead frames 11 to 13 is first formed, and thereafter the base body 10a is molded by a resin molding apparatus. The base body 10a is so molded that a front end portion 210c is aligned on the same plane as a front end surface 211e of the front end region 11a of the lead frame 11.

Thereafter, the sealant 15 is applied onto the inner surface of the opening 10d (the upper surface of the front end region 11a in the opening 10d and the respective inner surfaces of the pair of side wall portions 10f) in a state where the base 10 is heated to about 220° C. In a state where the sealant 15 is melted by heat, the window member 46 is thermocompression bonded and mounted by being fitted into the opening 10d. Thus, the window member 46 is mounted on the base body 10a while bringing the lower surface 46a and the both side surfaces 46c into close contact with the upper surface of the front end region 11a and the inner surfaces of the side wall portions 10f through the sealant 15.

Thereafter, UV cleaning treatment or heating treatment at about 200° C. in vacuum is performed on the base 10. Thus, contaminations attached to the recess portion 10b in the manufacturing process are removed, or moisture or a solvent contained in polyamide resin is evaporated to be removed.

Thereafter, the submount 40 to which the blue-violet semiconductor laser chip 20 and the PD 42 are bonded with a conductive adhesive layer (not shown) is bonded onto a substantially central portion (in a lateral direction) of the upper surface of the front end region 11a. At this time, a light-emitting surface of the blue-violet semiconductor laser chip 20 faces the window member 46, and the light-reflecting surface of the blue-violet semiconductor laser chip 20 and the PD 42 face the inner wall portion 10g.

Thereafter, a p-side electrode 21 of the blue-violet semiconductor laser chip 20 and a front end region 12a of the lead frame 12 are connected with each other through a metal wire 91. An upper surface of the PD 42 and a front end region 13a of the lead frame 13 are connected with each other through a metal wire 92.

The sealant 15 (EVOH resin) is applied with a thickness of about 0.2 mm onto the entire back surface 45c heated to about 220° C., and a nickel silver sheet is cut out to have the planar shape (see FIG. 9) substantially identical to the planar shape of the base body 10a after cooling, whereby the sealing member 45 is formed.

Thereafter, the sealing member 45 is thermocompression bonded onto the upper surface 10i and the upper surface 46b to cover the opening 10d in a state where the base 10 is heated to about 220° C. Thus, the sealing member 45 is mounted on the base body 10a while bringing the back surface 45c into close contact with the upper surface 10i and the upper surface 46b through the sealant 15. The remaining manufacturing process is substantially similar to that of the first embodiment.

According to the second embodiment, as hereinabove described, the opening 10d of the base body 10a is sealed with the window member 46 through the sealant 15, and the opening 10e of the base body 10a is sealed with the sealing member 45 through the sealant 15. The window member 46 and the sealing member 45 can be further strongly mounted on the base body 10a with no clearance by employing the sealant 15, and hence the package 90 can be reliably sealed. Thus, the blue-violet semiconductor laser chip 20 in the package 90 can be inhibited from deterioration.

Further, the openings 10d and 10e which open from the upper surface 10i to the front end portion 210c of the base body 10a are sealed with the window member 46 and the sealing member 45, respectively, and hence clearances are hardly generated in the boundaries of the upper surface 10i of the opening 10e and the front end portion 210c of the opening 10d. Thus, the package 90 can be reliably sealed, and hence the blue-violet semiconductor laser chip 20 in the package 90 can be reliably inhibited from deterioration.

Further, the window member 46 and the sealing member 45 are mounted to the base body 10a through the sealant 15, whereby the semiconductor laser apparatus 200 can be easily manufactured with existing manufacturing equipments without increasing the manufacturing cost.

### Third Embodiment

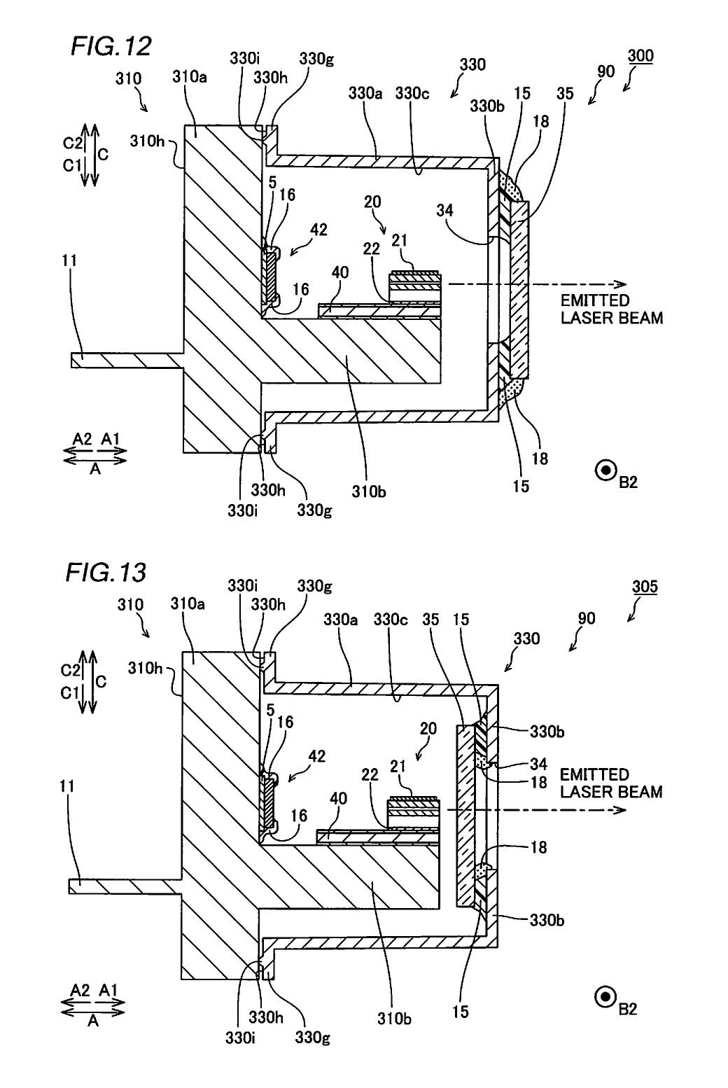

A semiconductor laser apparatus 300 according to a third embodiment of the present invention is now described. In this semiconductor laser apparatus 300, a package 90 is constituted by a metal base 310 and a metal cap 330, as shown in FIGS. 11 and 12. The cap 330 is an example of the “sealing member” in the present invention.

The base 310 is made of kovar, which is an Fe—Ni—Co alloy with an Ni—Au plated surface. The base 310 has a stem portion 310a with a prescribed thickness (in a direction A) formed in a substantially disc shape and a protruding block 310b protruding forward (in a laser beam-emitting direction (direction A1)), formed on a lower region (C1 side) of a front surface 310c of the stem portion 310a and having a semilunar cross section (in a width direction (direction B)).

The base 310 is provided with a lead frame 11 conducting to the stem portion 310a and lead frames 12 and 13 so arranged as to pass through the stem portion 310a from the front side to the back side (A2 side) in a state where the lead frames 12 and 13 are hermetically-closed by low-melting-point glass 319 such as kovar glass and isolated from the lead frame 11. Respective back end regions of the lead frames 11 to 13 extending backward are exposed from a back surface 310h on a back portion of the stem portion 310a.

A blue-violet semiconductor laser chip 20 is mounted on a substantially central portion of an upper surface of the protruding block 310b through a submount 40. A PD 42 is arranged on the front surface 310c of the stem portion 310a at a position opposed to a light-reflecting surface (A2 side) of the blue-violet semiconductor laser chip 20 such that a photodetecting surface faces forward. A lower surface (n-type region) of the PD 42 is electrically connected to the stem portion 310a through a conductive adhesive layer 5. A covering agent 16 is circumferentially applied to cover the outer periphery of the PD 42 excluding the photodetecting surface, a surface of the conductive adhesive layer 5 protruding along this outer periphery and a surface of the stem portion 310a in the periphery of the conductive adhesive layer 5.

The cap 330 has a body made of kovar with an Ni-plated surface and has a side wall portion 330a substantially cylindrically formed and a bottom portion 330b closing one side (A1 side) of the side wall portion 330a. A mounting portion 330g is circumferentially formed on an opening side (A2 side) of the side wall portion 330a of the cap 330. A protrusion 330i employed in resistance welding is formed on an end surface 330h of the mounting portion 330g.

A hole 34 is provided in a substantially central portion of the bottom portion 330b of the cap 330. A rectangular light transmission portion 35 made of borosilicate glass is provided to cover the hole 34 from the outside (A1 side) of the bottom portion 330b. At this time, the light transmission portion 35 is bonded to the bottom portion 330b through a sealant 15 with a thickness of about 0.1 mm applied onto an outer surface of the bottom portion 330b other than the hole 34.

As shown in FIG. 12, a covering agent 18 is circumferentially piled up so as to come into contact with the bottom portion 330b, the sealant 15 and the light transmission portion 35 along an outer edge of the light transmission portion 35. In other words, a side surface (outer surface) of the sealant 15 for bonding the bottom portion 330b and the light transmission portion 35 to each other is covered with the covering agent 18 made of a material having smaller water vapor permeability than the sealant 15. A material having low water vapor permeability is selected from among light curing or thermosetting resins made of epoxy resin or the like and employed as this covering agent 18. Therefore, the covering agent 18 prevents the sealant 15 from coming into direct contact with outside air. The covering agent 16 is not applied onto an inner surface 330c of the cap 330.

The remaining structure of the semiconductor laser apparatus 300 is substantially similar to that of the semiconductor laser apparatus 100 according to the first embodiment and denoted by the same reference numerals in the figures.

In a manufacturing process of the semiconductor laser apparatus 300, the submount 40 to which the blue-violet semiconductor laser chip 20 is bonded with a conductive adhesive layer (not shown) is first bonded onto the protruding block 310b of the base 310 provided with the lead frames 11 to 13, as shown in FIG. 11. Then, the lower surface (n-type region) of the PD 42 is bonded onto the front surface 310c behind the submount 40 and above the protruding block 310b with the conductive adhesive layer 5.

Thereafter, the outer periphery of the PD 42 is covered with a film of the covering agent 16 (EVOH resin) previously cut in a frame shape from an upper side of the PD 42 not to come into contact with the photodetecting surface. In this state, the base 310 is heated to about 200° C., whereby the covering agent 16 is melted and circumferentially covers the outer periphery of the PD 42 excluding the photodetecting surface, the surface of the conductive adhesive layer 5 protruding along this outer periphery and the surface of the stem portion 310a in the periphery of the conductive adhesive layer 5. After cooling the stem portion 310a, metal wires 91 and 92 are bonded.

Thereafter, the sealant 15 is applied around the hole 34 from the outside of the bottom portion 330b in a state where the cap 330 is heated to about 220° C. In a state where the sealant 15 is melted by heat, the light transmission portion 35 is press-bonded through the sealant 15 to cover the hole 34, and thereafter the cap 330 is cooled. Then, the covering agent 18 is piled up to cover the sealant 15 exposed along the outer edge of the light transmission portion 35. The cap 330 is formed in the aforementioned manner.

Finally, the cap 330 is mounted on the base 310 along arrow P (in a direction A2) shown in FIG. 11. At this time, the end surface 330h of the mounting portion 330g is mounted by resistance welding with a cap seal machine while circumferentially bringing the end surface 330h of the mounting portion 330g into contact with the vicinity of an outer edge of the stem portion 310a. Thus, the blue-violet semiconductor laser chip 20 is hermetically sealed. The remaining manufacturing process is substantially similar to that of the first embodiment. The semiconductor laser apparatus 300 is formed in the aforementioned manner.

According to the third embodiment, as hereinabove described, the cap 330 is cylindrically formed with the bottom portion 330b, and hence the package 90 can be sealed in a state where the blue-violet semiconductor laser chip 20 is circumferentially surrounded by an inner surface of the side wall portion 330a extending in a longitudinal direction (an extensional direction of a cylindrical shape (direction A)) of the cap 330.

The side surface (outer surface) of the sealant 15 for bonding the cap 330 (bottom portion 330b) and the light transmission portion 35 to each other is covered with the covering agent 18 made of a material having smaller water vapor permeability than the sealant 15. Thus, the covering agent 18 can reliably inhibit moisture or the like existing outside (in the atmosphere) from entering the package 90 through the sealant 15 from a bonded portion of the bottom portion 330b and the light transmission portion 35.

The cap 330 can be mounted on the stem portion 310a by resistance welding with a cap seal machine, similarly to a normal cap mounted with a light transmission portion through low-melting-point glass, and hence the semiconductor laser apparatus 300 can be easily manufactured with existing manufacturing equipments without increasing the manufacturing cost. The remaining effects of the third embodiment are similar to those of the first embodiment.

### Modification of Third Embodiment

A semiconductor laser apparatus 305 according to a modification of the third embodiment is now described. In this semiconductor laser apparatus 305, as shown in FIG. 13, a light transmission portion 35 is bonded through a sealant 15 to cover a hole 34 from the inside (inner surface 330c) of a bottom portion 330b of a cap 330. A covering agent 18 is circumferentially piled up to come into contact with the hole 34, the sealant 15 and the light transmission portion 35 in the vicinity of an inner surface of the hole 34 on which the light transmission portion 35 is mounted from inside. In other words, a side surface (inner surface) of the sealant 15 for bonding the bottom portion 330b and the light transmission portion 35 is covered with the covering agent 18. The remaining structure of the semiconductor laser apparatus 305 according to the modification of the third embodiment is substantially similar to that of the semiconductor laser apparatus 300 according to the third embodiment and denoted by the same reference numerals in the figure.

In a manufacturing process of the semiconductor laser apparatus 305 according to the modification of the third embodiment, the light transmission portion 35 is thermocompression bonded onto the inner surface 330c in the bottom portion 330b of the cap 330 through the sealant 15, and thereafter the covering agent 18 is piled up to cover the sealant 15 exposed on a side of the inner surface of the hole 34. The remaining manufacturing process is substantially similar to that of the third embodiment. The effects of the modification of the third embodiment are similar to those of the third embodiment.

### Fourth Embodiment

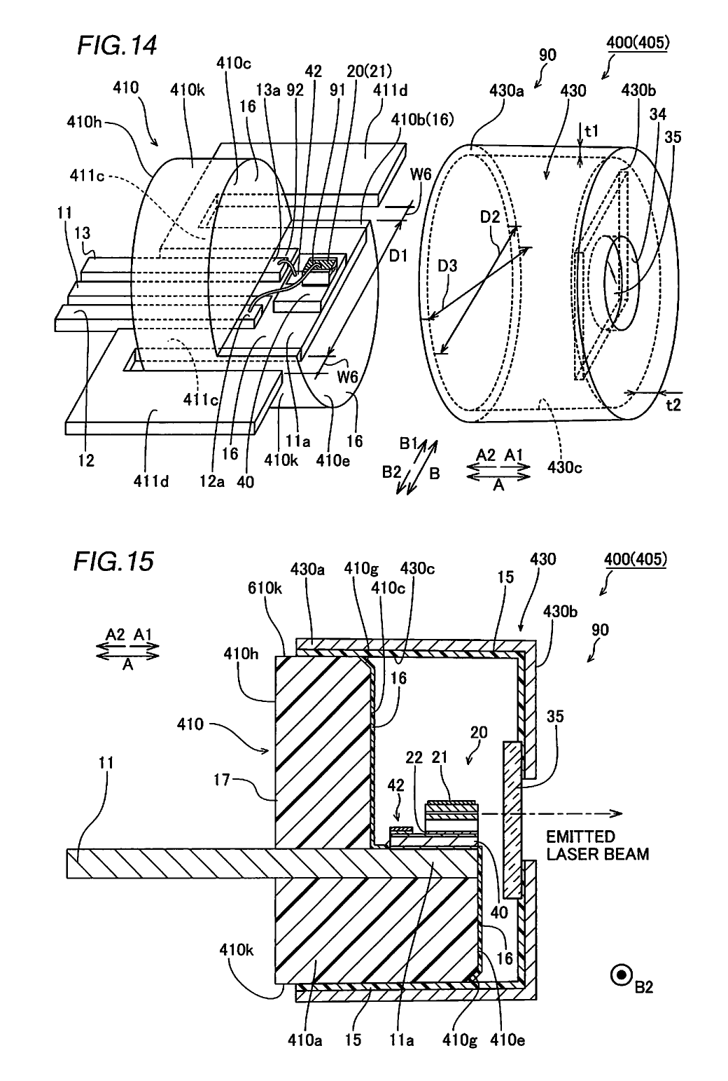

A semiconductor laser apparatus 400 according to a fourth embodiment of the present invention is now described. In this semiconductor laser apparatus 400, as shown in FIG. 14, a package 90 is constituted by a base 410 and a cap 430 both made of polyamide resin. The cap 430 is an example of the “sealing member” in the present invention.

The base 410 has a substantially cylindrical header portion 410a with an outer diameter D1 and a protruding block 410b extending forward (in a direction A1) from a lower half portion of a front surface 410c of the header portion 410a. As shown in FIG. 15, edges 410g where an outer peripheral surface 410k and front surfaces 410c and 410e of the base 410 intersect are chamfered.

A lead frame 11 is integrally formed with a pair of heat radiation portions 411d connected to a front end region 11a. Specifically, the lead frame 11 is formed with connecting portions 411c extending backward (in a direction A2) from both ends of the front end region 11a in a width direction (on B2 and B1 sides). The connecting portions 411c extend backward from the front end region 11a outside (on the B2 and B1 sides of) lead frames 12 and 13 and pass through a back surface 410h after hiding in the header portion 410a from the front surface 410c of the base 410. The heat radiation portions 411d are connected to back end regions of the connecting portions 411c exposed from the back surface 410h of the base 410. The heat radiation portions 411d extend forward (in the direction A1) from positions connected to the connecting portions 411c. Therefore, the pair of heat radiation portions 411d extend substantially parallel to the outer peripheral surface 410k at an interval of a width W6 from the outer peripheral surface 410k of the base 410, as shown in FIG. 14.

The cap 430 has a substantially cylindrical side wall portion 430a with an inner diameter D2 and an outer diameter D3 and a bottom portion 430b closing one side (A1 side) of the side wall portion 430a. The side wall portion 430a has a thickness t1 of about 0.5 mm, and the bottom portion 430b has a thickness t2 (t2≧t1) slightly larger than the thickness t1. The inner diameter D2 of the cap 430 is slightly smaller than the outer diameter D1 of the header portion 410a. The mounting portion 330g as in the third embodiment is not formed on an opening side (A2 side) of the side wall portion 430a. A sealant 15 is applied with a thickness of about 0.3 mm on a substantially entire region of an inner surface 430c of the cap 430 excluding a hole 34.

In this state, the header portion 410a is slid to the cap 430 from an A2 side toward an A1 side to be fitted into the cap 430 in the semiconductor laser apparatus 400, as shown in FIG. 15. In other words, the outer peripheral surface 410k of the header portion 410a and the inner surface 430c of the cap 430 are circularly fitted into each other through the sealant 15. Thus, a blue-violet semiconductor laser chip 20 is hermetically sealed in the package 90.

A covering agent 16 is applied onto a surface of each member located in sealed space (closed space surrounded by the base 410 and the cap 430) of the package 90. Specifically, the covering agent 16 continuously covers the protruding block 410b, the front surface 410c, the front surface 410e and the edges 410g of the base 410, a surface of the front end region 11a other than a portion onto which a submount 40 is bonded and surfaces of front end regions 12a and 13a to which metal wires are bonded with no clearance. Therefore, the surfaces of the base 410 of resin located in the sealed space of the package 90 and the front end regions 12a and 13a to which the metal wires are bonded are completely covered with the covering agent 16. The sealant 15 exposed in the sealed space of the package 90 of the aforementioned sealant 15 applied onto the inner surface 430c of the cap 430 also serves as the “covering agent” in the present invention. It is not necessary to cover a surface of a metal member with the covering agent 16.

Clearances (notches) each having a width W6 larger than the thickness t1 of the side wall portion 430a of the cap 430 are formed between the outer periphery surface 410k of the base 410 and the heat radiation portions 411d on both sides of the outer periphery surface 410k. Therefore, the heat radiation portions 411d are arranged outside the cap 430 without interfering in (coming into contact with) the side wall portion 430a of the cap 430 in a state where the cap 430 is fitted into the base 410. The remaining structure of the semiconductor laser apparatus 400 according to the fourth embodiment is substantially similar to that of the semiconductor laser apparatus 300 according to the third embodiment and denoted by the same reference numerals in the figures.

In a manufacturing process of the semiconductor laser apparatus 400 according to the fourth embodiment, the base 410 having the aforementioned shape is first molded through the manufacturing process similar to that of the second embodiment. Thereafter, the submount 40 to which the blue-violet semiconductor laser device 20 and the PD 42 are bonded is bonded onto the protruding block 410b of the base 410 provided with the lead frames 11 to 13 through a conductive adhesive layer (not shown).

Metal wires 91 and 92 are bonded, and thereafter the covering agent 16 is applied to continuously cover the protruding block 410b, the front surface 410c, the front surface 410e and the edges 410g of the base 410, the surface of the front end region 11a other than the portion onto which the submount 40 is bonded and the surfaces of the front end regions 12a and 13a to which the metal wires are bonded in a state where the base 410 is heated to about 230° C.

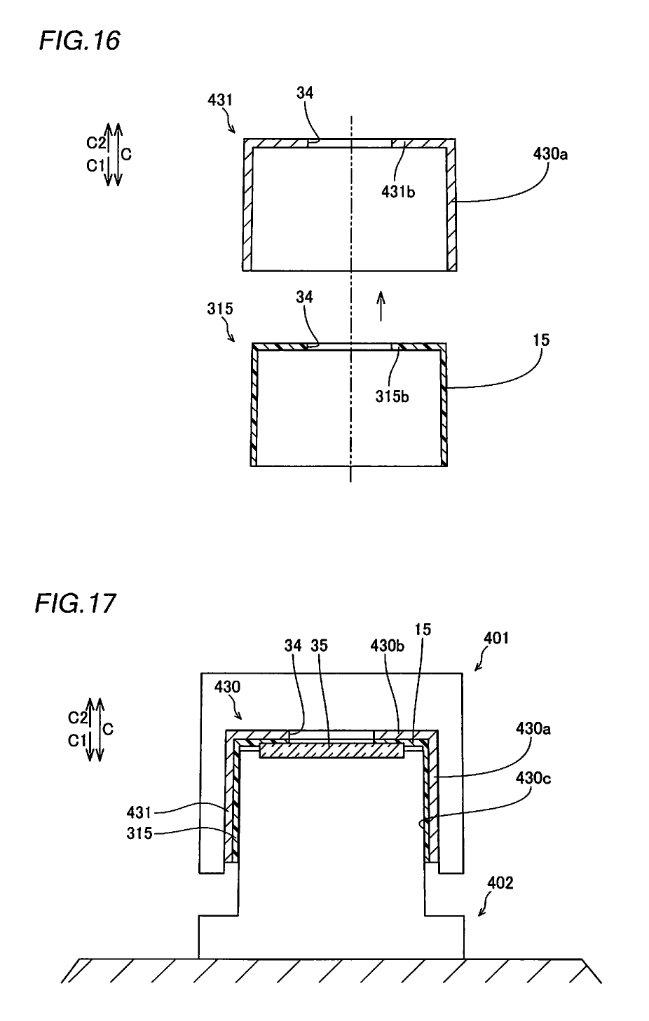

Meanwhile, polyamide resin is poured into a first mold (not shown) having a prescribed shape and hardened. Thus, a concave frame body 431 (see FIG. 16) becoming the cap 430, having the hole 34 in a bottom portion 431b is molded. EVOH resin heated to about 220° C. is poured into a second mold (not shown) having a prescribed shape, and thereafter cooled, whereby a concave frame body 315 (see FIG. 16) made of EVOH resin is molded. At this time, the hole 34 is also formed in a bottom portion 315b of the frame body 315.

The frame body 315 is covered with the frame body 431 from above (C2 side) in a state where the bottom portions 431b and 315b are opposed to each other and set between a movable upper mold 401 and a stationary lower mold 402. Thereafter, the movable upper mold 401 is fitted into the stationary lower mold 402 in a state where the molds are heated to about 220° C., as shown in FIG. 17. At this time, the frame bodies are thermocompression bonded to each other in a state where a light transmission portion 35 of glass formed in a substantially disc shape is placed on an upper surface (on the C2 side) of the stationary lower mold 402. Then, the molds are cooled thereby molding the cap 430. Drafts are provided on an inner surface of the movable upper mold 401 and an outer surface of the stationary lower mold 402. Thus, in the molded cap 430, an outer diameter of the side wall portion 430a (an inner diameter of the inner surface 430c) on a side (A2 side) where the side wall portion 430a opens is slightly larger than an outer diameter of the side wall portion 430a (an inner diameter of the inner surface 430c) in the vicinity of the bottom portion 430b.

Thereafter, the base 410 is linearly slid to the cap 430 to be fitted into the cap 430 in a state where the base 410 is heated to about 200° C. thereby sealing the package 90. The remaining manufacturing process is substantially similar to that of the third embodiment.

According to the fourth embodiment, as hereinabove described, the sealant 15 is formed on the entire inner surface 430c becoming a back surface of the cap 430, and hence the sealant 15 can effectively inhibit volatile organic gas from penetrating into the sealed space of the package 90 even if the volatile organic gas is generated from a resin material of the cap 430.

The sealant 15 is formed on the entire inner surface 430c of the cap 430, and hence the physical strength (rigidity) is increased by the sealant 15 even if a thickness of the molded polyamide resin is small. Consequently, the cap 430 having a prescribed magnitude of rigidity can be easily made.

The blue-violet semiconductor laser chip 20 is sealed by fitting the base 410 and the cap 430 into each other, whereby the inner surface 430c of the cap 430 can be easily brought into close contact with the outer peripheral surface 410k of the base 410, and hence the package 90 can be easily sealed. In other words, it is not necessary to employ an additional adhesive or the like for sealing, and hence generation of organic gas can be inhibited. The remaining effects of the fourth embodiment are similar to those of the third embodiment.

### Modification of Fourth Embodiment

A semiconductor laser apparatus 405 according to a modification of the fourth embodiment is now described. In this semiconductor laser apparatus 405, a cap 430 is made of aluminum foil. The remaining structure of the semiconductor laser apparatus 405 according to the modification of the fourth embodiment is substantially similar to that of the semiconductor laser apparatus 400 according to the fourth embodiment and denoted by the same reference numerals in the figures.

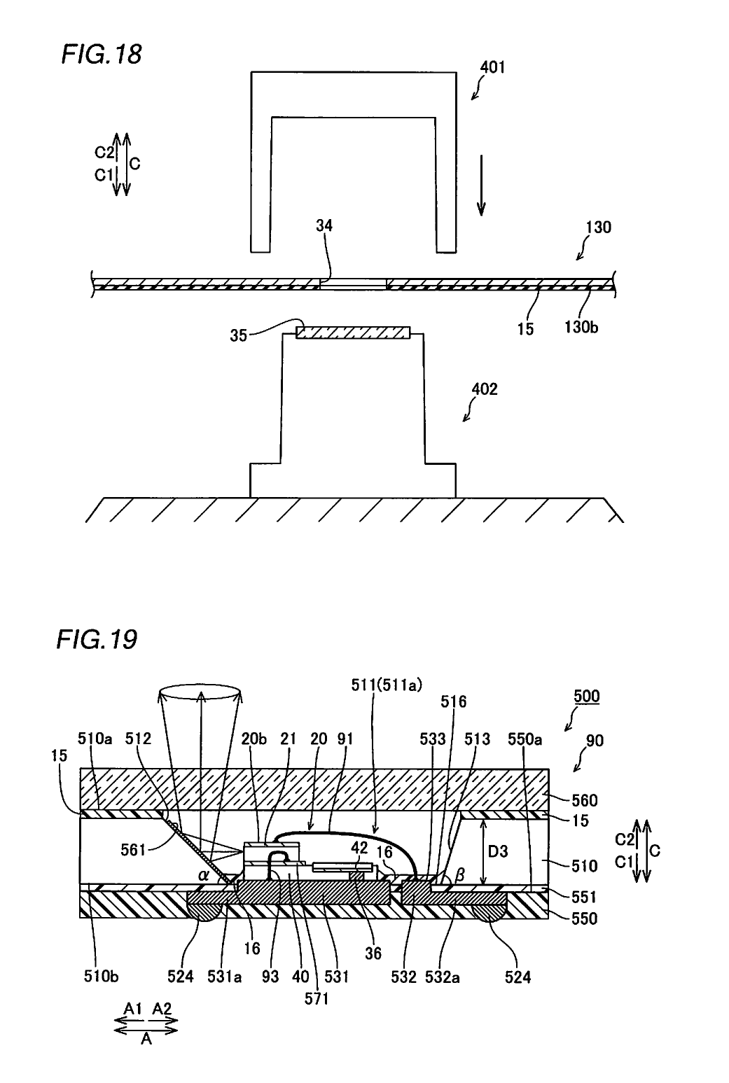

In a manufacturing process of the semiconductor laser apparatus 405 according to the modification of the fourth embodiment, as shown in FIG. 18, in a state where a sheet-like aluminum foil 130 having a thickness of about 20 μm is heated to about 220° C., a sealant 15 is applied with a thickness of about 0.2 mm on an entire lower (back) surface 131b and cooled, and thereafter a hole 34 is formed. Then, in a state where the aluminum foil 130 is set such that the sealant 15 faces downward (in a direction C1) between a movable upper mold 401 and a stationary lower mold 402, the movable upper mold 401 is fitted into the stationary lower mold 402. Thus, the cap 430 is molded. Corrugations are formed on an outer surface (inner surface) of a side wall portion 430a of the aluminum foil 130 substantially in the form of a cylinder by molding the cap 430. The remaining manufacturing process is substantially similar to that of the fourth embodiment. The effects of the modification of the fourth embodiment are similar to those of the fourth embodiment.

### Fifth Embodiment

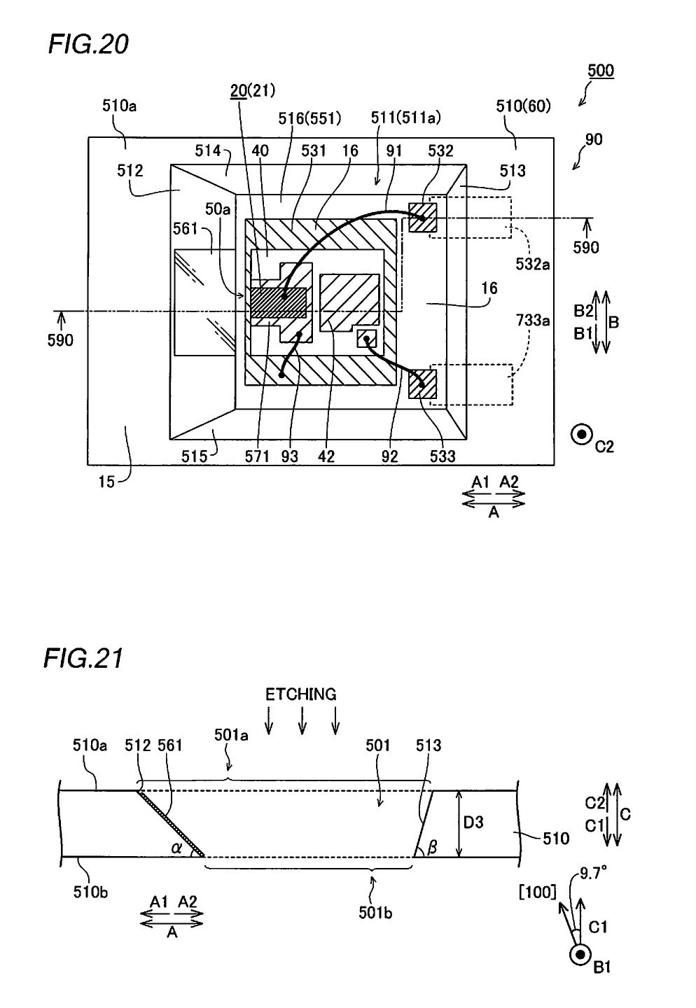

A semiconductor laser apparatus 500 according to a fifth embodiment of the present invention is now described. In this semiconductor laser apparatus 500, a package 90 has a base 550, an Si (100) substrate 510 mounted on the base 550, surrounding a blue-violet semiconductor laser chip 20 from the side (directions A and B) and sealing glass 560 mounted on the Si (100) substrate 510, covering the blue-violet semiconductor laser chip 20 from the upper side (C2 side), as shown in FIG. 19. The Si (100) substrate 510 and the sealing glass 560 are examples of the “sealing member” and the “window member” in the present invention, respectively. FIG. 19 is a sectional view taken along the line 590-590 in FIG. 20.

The base 550 is made of an insulating photo solder mask. The photo solder mask denotes an insulating coating of photosensitive resin becoming insoluble in a solvent or the like by structurally changing only a portion exposed to light. The base 550 closes an opening 501b (see FIG. 21) on one side (C1 side) of the Si (100) substrate 510 having a through hole 501 (see FIG. 21) penetrating in a thickness direction (direction C). At this time, the base 550 is bonded through adhesive resin 551 provided on a lower surface 510b of the Si (100) substrate 510. Thus, a recess portion 511 having an opening 511a which opens on the upper side is constituted by the base 550 and the Si (100) substrate 510. The blue-violet semiconductor laser chip 20 is placed on a submount 40 such that an upper surface 20b is located below (on a C1 side of) an upper surface 510a of the Si (100) substrate 510. The photo solder mask is an example of the “photosensitive resin” in the present invention.

The plate-like (tabular) sealing glass 560 is made of borosilicate glass (hard glass) with a thickness of about 500 μm. The sealing glass 560 is mounted on the upper surface 510a of the Si (100) substrate 510 through a sealant 15. In other words, the Si (100) substrate 510 is covered with the sealing glass 560 from the upper surface 510a so that the opening 511a of the recess portion 511 is closed, and the blue-violet semiconductor laser chip 20 placed on a bottom surface 516 of the recess portion 511 is hermetically sealed in the package 90. A planar shape of the sealing glass 560 is substantially identical to that of the Si (100) substrate 510.

As shown in FIG. 19, in a manufacturing process described later, the Si (100) substrate 510 having a main surface (upper surface 510a) inclined at about 9.7° with respect to a substantially (100) plane is anisotropically etched, whereby four inner surfaces 512, 513, 514 and 515 each having an Si (111) plane are formed on the Si (100) substrate 510. This Si (100) substrate 510 having the main surface inclined at about 9.7° is employed, whereby the inner surface 512 is inclined with an inclined angle α of about 45° with respect to an upper surface 550a (bottom surface 516) of the base 550 while the inner surface 513 is inclined with an inclined angle β of about 64.4° with respect to the upper surface 550a (bottom surface 516). The inner surfaces 514 and 515 (see FIG. 20) each are inclined with an inclined angle of about 54.7° with respect to the upper surface 550a (bottom surface 516).

The four inner surfaces 512, 513, 514 and 515 and the adhesive resin 551 formed on an upper surface (surface on the C2 side) of the base 550 constitute the recess portion 511. The adhesive resin 551 is employed to bond the Si (100) substrate 510 and the base 550, and the bottom surface 516 of the recess portion 511 is substantially constituted by a part of an upper surface of the adhesive resin 551, as shown in FIG. 19. The Si (100) substrate 510 has high resistivity (an insulating property) and a thickness of about 500 μm from the upper surface 510a to the lower surface 510b.

A wiring electrode 531 made of Cu or the like for die-bonding (bonding) the submount 40 is formed on a region (region becoming the bottom surface 516 of the recess portion 511) of the upper surface 550a of the base 550 (adhesive resin 551) exposed in the recess portion 511. Thus, a back surface (surface on the C2 side) of the submount 40 is bonded onto a surface of the wiring electrode 531 through a conductive adhesive layer (not shown) at a position deviating along arrow to an A1 side (a side closer to the inner surface 512) from a substantially central portion in the recess portion 511. The wiring electrode 531 exposed in the recess portion 511 has a larger plane area than the submount 40, and the submount 40 is placed in a region formed with the wiring electrode 531. The wiring electrode 531 has an extraction wiring portion 531a extending along a direction A1 from a position on which the submount 40 is placed.

A metal reflective film 561 is formed on a surface of a region of the inner surface 512 opposed to a light-emitting surface. Thus, in the semiconductor laser apparatus 500, a laser beam emitted in the direction A1 from the light-emitting surface of the blue-violet semiconductor laser chip 20 is reflected upward on the inner surface 512 (metal reflective film 561) of the recess portion 511, and thereafter transmitted through the sealing glass 560 to be emitted outward. The inner surface 512 and the metal reflective film 561 constitute reflecting means for reflecting the laser beam outward.

As shown in FIG. 20, wiring electrodes 532 and 533 for wire bonding each having a rectangular shape (a size of about 100 μm×about 100 μm) are formed on a region of the bottom surface 516 of the recess portion 511 not formed with the wiring electrode 531. In other words, the wiring electrode 532 is exposed in a region deviating to the inner surface 514 (B2 side) between the submount 40 and the inner surface 513, and the wiring electrode 533 is exposed in a region deviating to the inner surface 515 (B1 side) between the submount 40 and the inner surface 513. The wiring electrodes 532 and 533 have extraction wiring portions 532a and 533a extending along a direction A2.

Therefore, a first end of a metal wire 91 is bonded to a p-side electrode 21 formed on an upper surface of the blue-violet semiconductor laser chip 20, and a second end of the metal wire 91 is connected to the wiring electrode 532. A first end of a metal wire 92 is bonded to an upper surface (p-type region) of a PD 42, and a second end of the metal wire 92 is connected to the wiring electrode 533. The PD 42 is formed such that a lower surface (n-type region) and the wiring electrode 531 conduct with each other through an electrode 36 passing through the submount 40 vertically (in the direction C). A first end of a metal wire 93 is bonded to a pad electrode 571 onto which a lower surface (n-side electrode 22) of the blue-violet semiconductor laser chip 20 is bonded, and a second end of the metal wire 93 is connected to the wiring electrode 531. A solder ball 524 made of Au—Sn solder is formed on an end of each of the extraction wiring portions 531a, 532a and 533a.

A covering agent 16 is applied with a prescribed thickness onto a surface of each member located in sealed space (closed space surrounded by the base 550, the inner surfaces of the Si (100) substrate 510 and the sealing glass 560) of the package 90. Specifically, the covering agent 16 continuously covers a surface of the adhesive resin 551 in the recess portion 511, a surface of the wiring electrode 531 other than portions to which the submount 40 and the PD 42 are bonded and surfaces of the wiring electrodes 532 and 533 with no clearance. Therefore, surfaces of the base 550, the wiring electrodes 531 to 533, etc. located in the sealed space of the package 90 are completely covered with the covering agent 16. The remaining structure of the fifth embodiment is substantially similar to that of the first embodiment.

A manufacturing process of the semiconductor laser apparatus 500 according to the fifth embodiment is now described with reference to FIGS. 19 to 23.

As shown in FIG. 21, the Si (100) substrate 510 in a wafer state having a thickness D3 of about 500 μm and the main surface (upper surface 510a) inclined at about 9.7° with respect to the substantially (100) plane is prepared. Then, wet etching (anisotropic etching) employing an etching solution such as TMAH is performed on the Si (100) substrate 510 formed with an etching mask (not shown) having a prescribed mask pattern on the upper surface 510a, thereby forming the through hole 501 penetrating from the upper surface 510a to the lower surface 510b. Thus, a plurality of the through holes 501 having openings 501a and 501b are formed in the Si (100) substrate 510 in a wafer state.

At this time, the four different inner surfaces 512, 513, 514 and 515 are formed in the through hole 501 by etching corresponding to crystal orientation of Si. The inner surface 512 is an etched surface (inclined surface) inclined at about 45° (angle α) with respect to the upper surface 510a, and the inner surface 513 is an etched surface (inclined surface) inclined at about 64.4° (angle β) with respect to the upper surface 510a. The inner surfaces 514 and 515 (see FIG. 20) are etched surfaces inclined at about 54.7° with respect to the upper surface 510a of the Si (100) substrate 510.

Thereafter, the metal reflective film 561 is formed by evaporation, sputtering or the like on the region of the inner surface 512 opposed to the light-emitting surface (see FIG. 19) in a state where the blue-violet semiconductor laser chip 20 is placed.

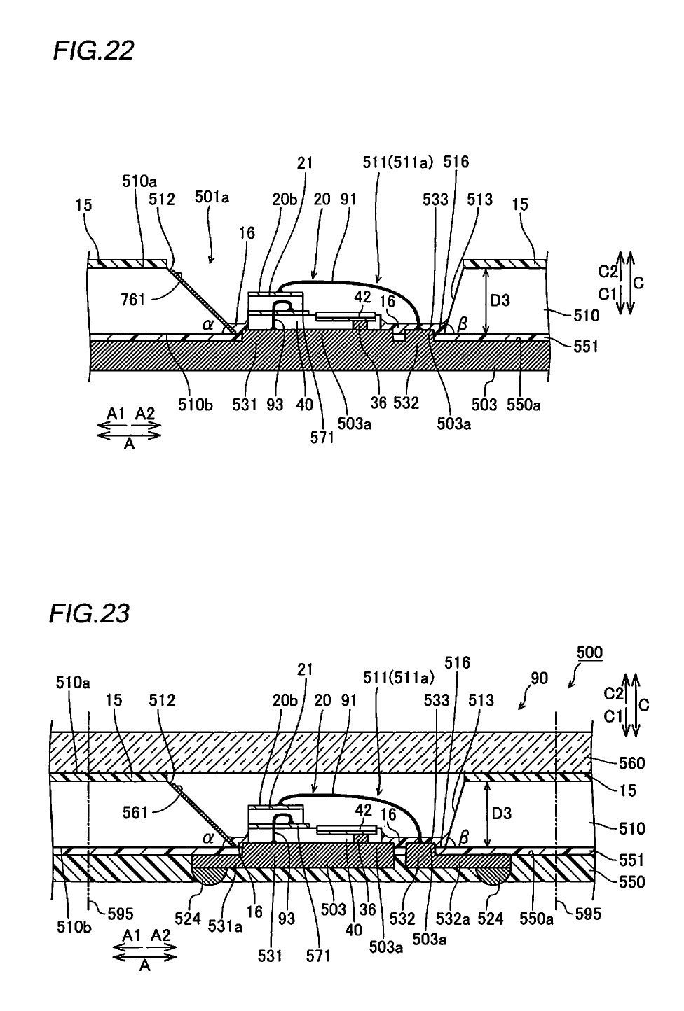

Meanwhile, a tabular copper plate 503 having a thickness of about 100 μm is prepared, as shown in FIG. 22. An etching mask (not shown) having a prescribed mask pattern is formed on an upper surface of the copper plate 503, and thereafter wet etching employing an etching solution such as a ferric chloride solution is performed on the copper plate 503. Thus, the copper plate 503 is etched from the upper and lower surfaces so that the flat portion has a thickness of about 60 μm, and a protrusion 503a having a protrusion height of about 20 μm is formed on the upper surface (a surface on the C2 side).

Thereafter, the thermosetting epoxy resin-based adhesive resin 551 is bonded onto the upper surface of the copper plate 503 by lamination with a roll laminator or a hot pressing machine. At this time, the adhesive resin 551 is bonded at a temperature of not more than about 100° C. at which the adhesive resin 551 does not harden completely. Thereafter, a portion of the adhesive resin 551 covering the protrusion 503a is removed by O₂ plasma treatment, polishing or the like.

Then, as shown in FIG. 22, the copper plate 503 is bonded onto the lower surface 510b of the Si (100) substrate 510 having the through hole 501 through the adhesive resin 551, and thereafter the Si (100) substrate 510 and the copper plate 503 are bonded to each other by thermocompression bonding for about 5 minutes under temperature and pressure conditions of about 200° C. and about 1 MPa. Thus, the opening 501b (see FIG. 21) of the Si (100) substrate 510 is closed so that the recess portion 511 is formed. The opening 501a of the Si (100) substrate 510 is left as the opening 511a in the upper portion of the recess portion 511.

Thereafter, the submount 40 to which the blue-violet semiconductor laser chip 20 is previously bonded is bonded onto the surface of the wiring electrode 531. Then, the A-side electrode 21 of the blue-violet semiconductor laser chip 20 and the wiring electrode 532 are connected with each other through the metal wire 91, and the p-type region of the PD 42 and the wiring electrode 533 are connected with each other through the metal wire 92. The pad electrode 571 and the wiring electrode 531 are connected with each other through the metal wire 93 (see FIG. 20). Before the metal wires 91 and 92 are bonded to the wiring electrodes 532 and 533, a metal film made of Au or the like may be formed on the surfaces of the wiring electrodes 532 and 533.

Thereafter, the covering agent 16 is applied onto the surface of the adhesive resin 551 in the recess portion 511, the surface of the wiring electrode 531 other than the portions to which the submount 40 and the PD 42 are bonded and the surfaces of the wiring electrodes 532 and 533 in a state where the Si (100) substrate 510 is heated to about 230° C.

Thereafter, the sealing glass 560 having a thickness of about 500 μm is bonded to the recess portion 511 of the Si (100) substrate 510 from the upper side by thermocompression bonding, as shown in FIG. 23. At this time, the Si (100) substrate 510 and the sealing glass 560 are bonded to each other with the sealant 15 under a temperature condition of at least about 200° C. and not more than about 220° C. Thus, the sealing glass 560 is bonded to the Si (100) substrate 510 through the sealant 15 in the upper surface 510a surrounding the opening 511a of the recess portion 511, and hence the inside of the recess portion 511 is hermetically sealed.

Thereafter, the lower surface of the copper plate 503 is etched to form a wiring pattern. Thus, the copper plate 503 other than the protrusion 503a has a thickness of about 20 μm. Further, an etching mask (not shown) having a prescribed mask pattern is formed on the lower surface of the copper plate 503, and thereafter wet etching employing a ferric chloride solution is performed on the copper plate 503, thereby forming the wiring electrodes 531 to 533 having prescribed wiring patterns constituted by the extraction wiring portions 531a, 532a and 533a (see FIG. 23). At this time, the adhesive resin 551 is partially exposed from under the removed copper plate 503.

Thereafter, a photo solder mask having a thickness of about 30 μm is formed on the lower surfaces of the wiring electrodes 531 to 533 and the exposed adhesive resin 551 to cover the lower surfaces of the wiring electrodes 531 to 533, as shown in FIG. 23. At this time, a laminated film of a photo solder mask may be bonded, or a liquid photo solder mask may be applied. Then, a lower surface of the photo solder mask is partially removed, and the solder balls 524 are formed on the ends of the extraction wiring portions 531a, 532a and 533a (see FIG. 20) exposed from the photo solder mask. The base 550 is formed in the aforementioned manner.

Finally, in a region outside a region formed with the recess portion 511, the sealing glass 560 and the Si (100) substrate 510 are cut (diced) in the thickness direction (direction C) along division lines 595 shown in FIG. 23 with a diamond blade. The semiconductor laser apparatus 500 according to the fifth embodiment shown in FIG. 20 is formed in the aforementioned manner.

According to the fifth embodiment, as hereinabove described, the semiconductor laser apparatus 500 comprises the Si (100) substrate 510 formed with the through hole 501 penetrating in the thickness direction, the sealing glass 560 mounted on the upper surface 510a of the Si (100) substrate 510, sealing the opening 501a (511a) of the through hole 501, the base 550 mounted on the lower surface 510b of the Si (100) substrate 510, sealing the opening 501b of the through hole 501 and the blue-violet semiconductor laser chip 20 placed on the surface of the wiring electrode 531 formed on the base 550 exposed in the opening 501b through the submount 40. Thus, the upper surface 20b of the blue-violet semiconductor laser chip 20 placed on the surface of the wiring electrode 531 exposed in the opening 501b does not protrude outward (to the C2 side in FIG. 19) beyond the opening 501a (511a) of the through hole 501, and hence the blue-violet semiconductor laser chip 20 can operate in a state where the same is hermetically sealed in the through hole 501 by the base 550 and the sealing glass 560. Thus, the blue-violet semiconductor laser chip 20 is not influenced by moisture in the atmosphere or an organic substance existing in the periphery of the semiconductor laser apparatus 500, and hence reduction of the reliability of the blue-violet semiconductor laser chip 20 can be inhibited.

The laser beam emitted from the blue-violet semiconductor laser chip 20 is reflected by the metal reflective film 561 formed on the inner surface 512 of the through hole 501, and thereafter transmitted through the sealing glass 560 to be emitted outward. Thus, the inner surface 512, which is a part of the through hole 501 of the Si (100) substrate 510 fixed onto the base 550 on which the blue-violet semiconductor laser chip 20 is placed through the submount 40, can also serve the reflecting means of the laser beam. In other words, precision of an optical axis of the laser beam reflected by the metal reflective film 561 formed on the inner surface 512 depends only on an arrangement error in placing the blue-violet semiconductor laser chip 20 on the surface of the wiring electrode 531 formed on the base 550 through the submount 40, and hence the number of factors causing deviation of the optical axis is reduced so that the magnitude of the deviation of the optical axis can be reduced.

The semiconductor laser apparatus 500 comprises the Si (100) substrate 510 formed with the through hole 501, the base 550 mounted on the lower surface 510b of the Si (100) substrate 510, sealing the opening 501b of the through hole 501 and the blue-violet semiconductor laser chip 20 placed on the surface of the wiring electrode 531 exposed in the opening 501b. Thus, a support base on which the blue-violet semiconductor laser chip 20 is placed can be formed as a different member employing a different material from the Si (100) substrate 510, and hence the strength of the semiconductor laser apparatus 500 can be further secured. In the manufacturing process, the Si (100) substrate 510 formed with the through hole 501 and the tabular base 550 are bonded to each other through the adhesive resin 551, whereby the package 90 for placing the blue-violet semiconductor laser chip 20 inside can be easily formed.

When wet etching is performed on the Si (100) substrate 510, the through hole 501 passing through the Si (100) substrate 510 is formed thereby forming the inner surfaces 512, 513, 514 and 515, and hence dispersion of the etching depth resulting when wet etching stops in the substrate does not result. Further, the blue-violet semiconductor laser chip 20 placed on the base 550 (copper plate 503) can be placed in the recess portion 511 in a state where precision of arrangement is excellent. Thus, in the manufacturing process, deviation of the optical axis of the laser beam and dispersion of the distance from the light-emitting surface to the metal reflective film 561 resulting from an angle (angle in a vertical direction with respect to a cavity direction or a width direction) in which the blue-violet semiconductor laser chip 20 is placed can be effectively inhibited.

The blue-violet semiconductor laser chip 20 is placed on the wiring electrode 531 (copper plate 503) having excellent thermal conductivity through the submount 40, and hence heat of the blue-violet semiconductor laser chip 20 can be efficiently radiated through the wiring electrode 531 (copper plate 503).

The Si (100) substrate 510 having the main surface inclined at about 9.7° with respect to the substantially (100) plane is employed, whereby the four inner surfaces 512 to 515 can be formed simultaneously with wet etching when the through hole 501 is formed in the Si (100) substrate 510 by the wet etching. Consequently, the manufacturing process is simplified, and hence the semiconductor laser apparatus 500 can be efficiently manufactured.

The plurality of through holes 501 are simultaneously formed in the Si (100) substrate 510 in a wafer state, whereby the plurality of through holes 501 can be simultaneously formed through a single etching step, and hence the semiconductor laser apparatus 500 can be efficiently manufactured.

The sealing glass 560 in a wafer state is bonded to a wafer in which the blue-violet semiconductor laser chip 20 is placed on the bottom surface 516 of each of a plurality of the recess portions 511 (wafer in which the base 550 is bonded to the Si (100) substrate 510) by thermocompression bonding, thereby sealing the recess portions 511. Thus, the plurality of recess portions 511 can be simultaneously hermetically sealed through a step of bonding a single piece of the sealing glass 560, and hence the semiconductor laser apparatus 500 can be efficiently manufactured. The remaining effects of the fifth embodiment are similar to those of the first embodiment.

### Sixth Embodiment

An optical pickup 600 according to a sixth embodiment of the present invention is now described. The optical pickup 600 is an example of the “optical apparatus” in the present invention.

The optical pickup 600 comprises a three-wavelength semiconductor laser apparatus 605, an optical system 620 adjusting laser beams emitted from the three-wavelength semiconductor laser apparatus 605 and a light detection portion 630 receiving the laser beams, as shown in FIG. 25.

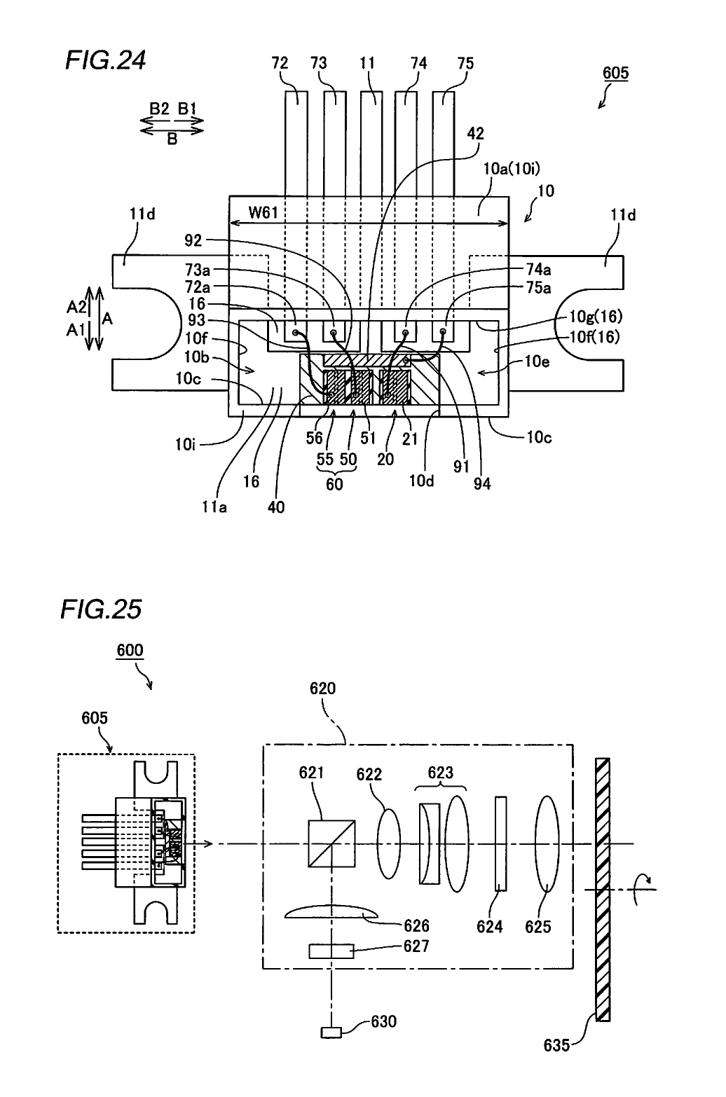

The three-wavelength semiconductor laser apparatus 605 is mounted with a blue-violet semiconductor laser chip 20 and a two-wavelength semiconductor laser chip 60 having a red semiconductor laser element 50 with a lasing wavelength of about 650 nm and an infrared semiconductor laser element 55 with a lasing wavelength of about 780 nm monolithically formed on a submount 40 in a package 90 adjacent to the blue-violet semiconductor laser chip 20, as shown in FIG. 24. The three-wavelength semiconductor laser apparatus 605 is an example of the “semiconductor laser apparatus” in the present invention, and the red semiconductor laser element 50, the infrared semiconductor laser element 55 and the two-wavelength semiconductor laser chip 60 are examples of the “semiconductor laser chip” in the present invention.

A base 10 is provided with lead frames 11, 72, 73, 74 and 75 made of metal. These lead frames 11 and 72 to 75 are so arranged as to pass through the base 10 from the front side (A1 side) to the back side (A2 side) in a state of being isolated from each other by resin mold. Back end regions extending to the outside (A2 side) of the base 10 each are connected to a driving circuit (not shown). Front end regions 11a, 72a, 73a, 74a and 75a extending to the front side (A1 side) of the lead frames 11 and 72 to 75 are exposed from an inner wall portion 10g and arranged on a bottom surface of a recess portion 10b.

A first end of a metal wire 91 is bonded to a p-side electrode 21, and a second end of the metal wire 91 is connected to the front end region 74a of the lead frame 74. A first end of a metal wire 92 is bonded to a p-side electrode 51 formed on an upper surface of the red semiconductor laser element 50, and a second end of the metal wire 92 is connected to the front end region 73a of the lead frame 73. A first end of a metal wire 93 is bonded to a p-side electrode 56 formed on an upper surface of the infrared semiconductor laser element 55, and a second end of the metal wire 93 is connected to the front end region 72a of the lead frame 72. An n-side electrode (not shown) formed on a lower surface of the blue-violet semiconductor laser chip 20 and an n-side electrode (not shown) formed on a lower surface of the two-wavelength semiconductor laser chip 60 are electrically connected to the front end region 11a of the lead frame 11 through the submount 40.

A first end of a metal wire 94 is bonded to an upper surface of a PD 42, and a second end of the metal wire 94 is connected to the front end region 75a of the lead frame 75.

A cross section of the base 10 is elongated in a width direction (direction B), whereby a base body 10a has a maximum width W61 (W61>W1), as compared with the aforementioned semiconductor laser apparatus 100 according to the first embodiment. Therefore, an opening 10d in a front portion of the recess portion 10b is also elongated in the direction B. The remaining structure of the three-wavelength semiconductor laser apparatus 605 is substantially similar to that of the semiconductor laser apparatus 100 according to the first embodiment, and the structure similar to that of the first embodiment is denoted by the same reference numerals in the figure.

In a manufacturing process of the three-wavelength semiconductor laser apparatus 605, the blue-violet semiconductor laser chip 20 and the two-wavelength semiconductor laser chip 60 are aligned in a lateral direction (direction B in FIG. 24) and bonded through the submount 40. Thereafter, the respective p-side electrodes 21, 51 and 56 of the laser chips 20 and 60 and the upper surface of the PD 42 and the front end regions 72a, 73a, 74a and 75a of the lead frames 72, 73, 74 and 75 are wire-bonded to each other. The remaining manufacturing process is substantially similar to that of the first embodiment.

The optical system 620 has a polarizing beam splitter (PBS) 621, a collimator lens 622, a beam expander 623, a λ/4 plate 624, an objective lens 625, a cylindrical lens 626 and an optical axis correction device 627.

The PBS 621 totally transmits the laser beams emitted from the three-wavelength semiconductor laser apparatus 605, and totally reflects the laser beams fed back from an optical disc 635. The collimator lens 622 converts the laser beams emitted from the three-wavelength semiconductor laser apparatus 605 and transmitted through the PBS 621 to parallel beams. The beam expander 623 is constituted by a concave lens, a convex lens and an actuator (not shown). The actuator has a function of correcting wave surface states of the laser beams emitted from the three-wavelength semiconductor laser apparatus 605 by varying a distance between the concave lens and the convex lens in response to a servo signal from a servo circuit described later.

The λ/4 plate 624 converts the linearly polarized laser beams, substantially converted to the parallel beams by the collimator lens 622, to circularly polarized beams. Further, the λ/4 plate 624 converts the circularly polarized laser beams fed back from the optical disc 635 to linearly polarized beams. A direction of linear polarization in this case is orthogonal to a direction of linear polarization of the laser beams emitted from the three-wavelength semiconductor laser apparatus 605. Thus, the PBS 621 substantially totally reflects the laser beams fed back from the optical disc 635. The objective lens 625 converges the laser beams transmitted through the λ/4 plate 624 on a surface (recording layer) of the optical disc 635. An objective lens actuator (not shown) renders the objective lens 625 movable in a focus direction, a tracking direction and a tilt direction in response to servo signals (a tracking servo signal, a focus servo signal and a tilt servo signal) from the servo circuit described later.

The cylindrical lens 626, the optical axis correction device 627 and the light detection portion 630 are arranged to be along optical axes of the laser beams totally reflected by the PBS 621. The cylindrical lens 626 provides the incident laser beams with astigmatic action. The optical axis correction device 627 is constituted by a diffraction grating and so arranged that spots of zero-order diffracted beams of blue-violet, red and infrared laser beams transmitted through the cylindrical lens 626 coincide with each other on a detection region of the light detection portion 630 described later.

The light detection portion 630 outputs a playback signal on the basis of intensity distribution of the received laser beams. The light detection portion 630 has a detection region of a prescribed pattern, to obtain a focus error signal, a tracking error signal and a tilt error signal along with the playback signal. Thus, the optical pickup 600 comprising the three-wavelength semiconductor laser apparatus 605 is formed.

In this optical pickup 600, the three-wavelength semiconductor laser apparatus 605 can independently emit blue-violet, red and infrared laser beams from the blue-violet semiconductor laser chip 20, the red semiconductor laser element 50 and the infrared semiconductor laser element 55 by independently applying voltages between the lead frame 11 and the respective lead frames 72 to 74. The laser beams emitted from the three-wavelength semiconductor laser apparatus 605 are adjusted by the PBS 621, the collimator lens 622, the beam expander 623, the λ/4 plate 624, the objective lens 625, the cylindrical lens 626 and the optical axis correction device 627 as described above, and thereafter applied onto the detection region of the light detection portion 630.

When data recorded in the optical disc 635 is play backed, the laser beams emitted from the blue-violet semiconductor laser chip 20, the red semiconductor laser element 50 and the infrared semiconductor laser element 55 are controlled to have constant power and applied to the recording layer of the optical disc 635, so that the playback signal outputted from the light detection portion 630 can be obtained. The actuator of the beam expander 623 and the objective lens actuator driving the objective lens 625 can be feedback-controlled by the focus error signal, the tracking error signal and the tilt error signal simultaneously outputted.

When data is recorded in the optical disc 635, the laser beams emitted from the blue-violet semiconductor laser chip 20 and the red semiconductor laser element 50 (infrared semiconductor laser element 55) are controlled in power and applied to the optical disc 635, on the basis of the data to be recorded. Thus, the data can be recorded in the recording layer of the optical disc 635. Similarly to the above, the actuator of the beam expander 623 and the objective lens actuator driving the objective lens 625 can be feedback-controlled by the focus error signal, the tracking error signal and the tilt error signal outputted from the light detection portion 630.

Thus, the data can be recorded in or played back from the optical disc 635 with the optical pickup 600 comprising the three-wavelength semiconductor laser apparatus 605.

The optical pickup 600 comprises the three-wavelength semiconductor laser apparatus 605. In other words, the blue-violet semiconductor laser chip 20 and the two-wavelength semiconductor laser chip 60 are reliably sealed in the package 90. Thus, the reliable optical pickup 600 having the semiconductor laser chips hard to deteriorate, capable of enduring the use for a long time can be obtained. The effects of the three-wavelength semiconductor laser apparatus 605 are similar to those of the semiconductor laser apparatus 100 according to the first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the surfaces of the lead frames arranged in the sealed space of the base are also covered with the covering agent 16 in each of the first, second and fourth embodiments, the present invention is not restricted to this, but the covering agent 16 may be applied onto only the surface of the base (resin material) other than the lead frames (metal portions).

While the sealant 15 is applied onto the substantially entire back surface 45c of the sealing member 45 in the aforementioned second embodiment, the present invention is not restricted to this, but the sealant 15 may not be applied onto the back surface 45c of the sealing member 45 located in the sealed space of the package 90 so that the surface of the nickel silver sheet may be exposed in the sealed space, similarly to the modification of the first embodiment.

While the gas absorbent 49 is not provided in the package 90 in each of the aforementioned second to fifth embodiments, the present invention is not restricted to this, but the gas absorbent 49 may be provided, similarly to the aforementioned first embodiment. In this case, silica gel may be employed as the gas absorbent 49, or synthetic zeolite, calcium oxide-based absorbent material, activated charcoal or the like other than silica gel, for example, may be employed as the gas absorbent 49. Synthetic zeolite in the form of a pellet (a cylindrical shape) may be cut in a prescribed size and fixed in the sealed space of the package 90.

While the sealant 15 is applied to the periphery of the hole (window portion) of the sealing member, and thereafter the light transmission portion 35 is thermocompression bonded in the manufacturing process of each of the aforementioned first, third and fourth embodiments, the present invention is not restricted to this. For example, EVOH resin previously formed in the form of a thin film may be cut and placed on the periphery of the hole 34, and thereafter the light transmission portion 35 may be thermocompression bonded.

While the “sealing member” in the present invention is made of aluminum foil in the aforementioned first embodiment, in the present invention, the sealing member may be formed by employing Cu foil, Cu alloy foil such as nickel silver, Sn foil, stainless steel foil or the like as metal foil other than aluminum foil, for example.

While the base 410 and the cap 430 are made of polyamide resin in the aforementioned fourth embodiment, the base 410 and the cap 430 may be made of resin with low water vapor permeability other than polyamide resin, and permeation of moisture can be sufficiently inhibited.

While the base is sealed in a state where the sealant 15 made of EVOH resin is formed on the back surface of the “sealing member” in the present invention made of aluminum foil in the aforementioned first embodiment, in the present invention, the sealing member may be formed by employing epoxy resin or the like other than metal, for example and mounted on the base through the sealant 15 arranged on the back surface. If the aforementioned resin material is employed as the sealing member, EVOH resin (sealant 15) having excellent gas barrier properties can more effectively inhibit low molecular siloxane, volatile organic gas or the like from entering the package 90.

While the “sealing member” in the present invention is made of a nickel silver (Cu alloy) sheet in the aforementioned second embodiment, in the present invention, the sealing member may be formed by employing an aluminum plate, a Cu plate, an alloy plate such as Sn, Ni and Mg, a stainless steel plate or the like other than the nickel silver sheet, for example.

Further, multilayer metal oxide films (dielectric films) of Al₂O₃, SiO₂, ZrO₂ and the like may be formed as gas barrier layers on surfaces of the light transmission portion (sealing glass) also in each of the aforementioned third to fifth embodiments. Alternatively, metal films of Al, Ni, Pt, Au or the like may be formed. Metal films may be formed on surfaces of a lead frame resin member in each of the first, second and sixth embodiments.

While the sealant 15 is applied onto one surface of the sealing member in a state where the sealing member is heated to about 220° C. in the manufacturing process of each of the aforementioned first, second, fourth and fifth embodiments, in the present invention, the sealing member may be heated to remove solvent after a mixture of the solvent and EVOH resin prepared by dissolving the EVOH resin in the solvent is applied to the sealing member.

While the base body 10a is made of polyamide resin (PA) in each of the aforementioned first and second embodiments, in the present invention, the base may be made of epoxy resin, polyphenylene sulfide resin (PPS), a liquid crystal polymer (LCP) or the like. At this time, the base body 10a can be molded in a state of a mixture obtained by introducing a gas absorbent into a resin material at a prescribed ratio. The gas absorbent is preferably prepared from a granular absorbent having a particle diameter of at least several 10 μm and not more than several 100 μm.

While the depth of the recess portion 10b of the base 10 is about half the thickness t1 of the base body 10a in each of the aforementioned first and second embodiments, the present invention is not restricted to this, but the depth of the recess portion 10b may be deeper or shallower than the thickness t1/2, for example.

While the side surfaces (the outer surface and the inner surface) of the sealant 15 for bonding the cap 330 and the light transmission portion 35 to each other are covered with the covering agent 18 in each of the aforementioned third embodiment and the modification thereof, the present invention is not restricted to this, but side surfaces of the sealant 15 for bonding the sealing member and the window member in another embodiment to each other may be covered with this covering agent 18. An oxide film of Al₂O₃, SiO₂, ZrO₂ or the like or a metal thin film of Al, Pt, Ag, Au, Pd, Ni or the like other than the resin may be employed as the covering agent 18, and the resin may contain a high proportion of binders of an inorganic material such as SiO₂. In addition to the side surfaces of the sealant 15, resin surfaces of PA, PPS, LCP, etc. may be covered with the covering agent 18, and moisture can be inhibited from penetrating into the PA, PPS and LCP.

While the optical pickup 600 comprising the “semiconductor laser apparatus” in the present invention has been shown in the aforementioned sixth embodiment, the present invention is not restricted to this, but the semiconductor laser apparatus in the present invention may be applied to an optical disc apparatus performing record in and playback of an optical disc such as a CD, a DVD or a BD. Further, an RGB three-wavelength semiconductor laser apparatus as the “semiconductor laser apparatus” in the present invention may be constituted by red, green and blue semiconductor laser chips, and this RGB three-wavelength semiconductor laser apparatus may be applied to an optical apparatus such as a projector.

What is claimed is:

1. A semiconductor laser apparatus comprising:
a package constituted by a plurality of members, having sealed space inside; and
a semiconductor laser chip arranged in said sealed space, wherein
surfaces of said members located in said sealed space are covered with a covering agent made of an ethylene-polyvinyl alcohol copolymer.

2. The semiconductor laser apparatus according to claim 1, wherein
said package includes a resin member containing a volatile component, and
a surface of said resin member located in said sealed space is covered with said covering agent.

3. The semiconductor laser apparatus according to claim 1, further comprising a metal plate for mounting said semiconductor laser chip on an inner bottom surface of said package, wherein
a surface of said metal plate other than a region on which said semiconductor laser chip is placed is covered with said covering agent.

4. The semiconductor laser apparatus according to claim 3, wherein
said package includes a resin member containing a volatile component, and
a surface of said resin member located in said sealed space and said surface of said metal plate other than said region on which said semiconductor laser chip is placed are continuously covered with said covering agent.

5. The semiconductor laser apparatus according to claim 2, wherein
said package includes a base made of resin, mounted with said semiconductor laser chip, and
a surface of said base located in said sealed space is covered with said covering agent.

6. The semiconductor laser apparatus according to claim 5, wherein
said base is made of one of polyamide resin, epoxy resin, polyphenylene sulfide resin, a liquid crystal polymer and photosensitive resin.a

7. The semiconductor laser apparatus according to claim 1, further comprising a photodetector arranged in said sealed space, monitoring an intensity of a laser beam from said semiconductor laser chip, wherein
said photodetector is fixed through a conductive adhesive layer containing a volatile component in said sealed space, and
a surface of said conductive adhesive layer fixing said photodetector exposed in said sealed space is covered with said covering agent.

8. The semiconductor laser apparatus according to claim 1, wherein
said package includes a base and a sealing member mounted on said base, and
at least a surface of said sealing member located in said sealed space is covered with said covering agent.

9. The semiconductor laser apparatus according to claim 8, wherein
a substantially entire surface of said sealing member on a side bonded to said base including said surface of said sealing member located in said sealed space is covered with said covering agent.

10. The semiconductor laser apparatus according to claim 9, wherein
said covering agent is arranged on a bonded region of said sealing member and said base.

11. The semiconductor laser apparatus according to claim 10, wherein
said sealing member is bonded to said base with said covering agent arranged on said bonded region of said sealing member and said base.

12. The semiconductor laser apparatus according to claim 9, wherein
said sealing member is made of metal foil, and
substantially entire inner surface of said sealing member made of said metal foil having a side cross section bent in a substantially L-shaped manner from an upper surface to a front surface of said base is covered with said covering agent.

13. The semiconductor laser apparatus according to claim 8, wherein
said base has a recess portion provided with an opening from an upper surface to a front surface, and
an inner surface of said recess portion and an inner surface of said sealing member are continuously covered with said covering agent.

14. The semiconductor laser apparatus according to claim 8, wherein
said sealing member is made of elastic resin,
said package is sealed by fitting said base and said sealing member into each other, and
surfaces of said base and said sealing member exposed in said sealed space are covered with said covering agent.

15. The semiconductor laser apparatus according to claim 14, wherein
said sealing member is cylindrically formed with a bottom portion,
a cylindrical inner peripheral surface of said sealing member is circularly fitted into an outer peripheral surface of said base, and
said covering agent is arranged on a region in which said base and said sealing member are circularly fitted into each other in addition to said surfaces of said base and said sealing member exposed in said sealed space.

16. The semiconductor laser apparatus according to claim 1, wherein
said package includes a sealing member mounted on said base and a window member transmitting a laser beam emitted from said semiconductor laser chip to an outside of said package, and
said window member is bonded to said sealing member with said covering agent arranged on a surface of said sealing member other than an opening formed in said sealing member.

17. The semiconductor laser apparatus according to claim 1, wherein
a gas absorbent is set in said sealed space of said package.

18. The semiconductor laser apparatus according to claim 17, wherein
said gas absorbent is sandwiched in contact with said covering agent in said sealed space to be fixed.

19. The semiconductor laser apparatus according to claim 1, wherein
said semiconductor laser chip includes a nitride-based semiconductor laser chip.

20. An optical apparatus comprising:
a semiconductor laser apparatus including a package constituted by a plurality of members, having sealed space inside and a semiconductor laser chip arranged in said sealed space; and
an optical system controlling a beam emitted from said semiconductor laser apparatus, wherein
surfaces of said members located in said sealed space are covered with a covering agent made of an ethylene-polyvinyl alcohol copolymer.
